(19) United States
(12) Patent Application Publication
(10) Pub. No.: US 2008/0007364 A1
(43) Pub. Date: Jan. 10, 2008

(54) Voltage controlled oscillator

(75) Inventor: Tadashi Chiba, Tokyo (JP)

Correspondence Address: RABIN & Berdo, PC, 1101 14TH STREET, NW, SUITE 500, WASHINGTON, DC, 20005, US

(73) Assignee: OKI ELECTRIC INDUSTRY CO., LTD., Tokyo (JP)

(21) Appl. No.: 11/783,481

(22) Filed: Apr. 10, 2007

(30) Foreign Application Priority Data
Jun. 15, 2006 (JP) 2006-165810

(51) Int. Cl. H03B 5/12

(52) U.S. Cl. 331/177 V

(57) ABSTRACT

A voltage controlled oscillator (VCO) conducts current on two paths through parallel inductors and parallel cross-coupled metal-oxide-semiconductor transistors. A pair of varactors are connected in series on a third path extending from a node between one inductor and one transistor to a node between the other inductor and the other transistor. The oscillation frequency is controlled by a voltage applied to a node between the two varactors on the third path. Each varactor is structured as a metal-oxide-semiconductor transistor with interconnected source and drain electrodes, a gate electrode, a body region below the gate electrode, and a body terminal region extending beyond the gate electrode. An adjustment voltage applied to the body terminal region shifts the voltage-capacitance curve of the varactor and the voltage-frequency curve of the VCO without changing the shapes of these curves, providing a simple way to adjust the VCO to meet application requirements.

### BACKGROUND OF THE INVENTION

1. Field of the Invention

The present invention relates to a voltage controlled oscillator (VCO) incorporated into a semiconductor integrated circuit to generate a high-frequency signal.

2. Description of the Related Art

Advances in complementary metal-oxide-semiconductor (CMOS) fabrication technology have made it possible to fabricate, on a single semiconductor chip, devices having a variety of structures that include both active elements such as transistors and diodes and passive elements such as resistors, inductors, and capacitors. A VCO is one of these types of devices. VCOs are used, for example, in phase locked loops (PLLs) to synthesize high-frequency signals for numerous applications in a wide variety of chips.

FIG. 1 shows the basic PLL structure. The PLL 10 includes a phase comparator 30, a low pass filter (LPF) 40, and a VCO 45. The phase comparator 30 receives a reference signal fᵣ from an input terminal and receives the signal f_{VCO} output from the VCO 45. The reference signal is generated by dividing a clock signal output from a crystal oscillator (not shown) and has a predetermined frequency. The VCO output signal has a frequency determined by a control voltage signal output from the LPF 40, this frequency generally being several times the frequency of the reference signal.

The phase comparator 30 compares the phase of the VCO output signal f_{VCO} with the phase of the reference signal fᵣ and outputs a phase error signal representing the phase difference. The LPF 40 filters the phase error signal and extracts its low-frequency component to generate the control voltage signal supplied to the VCO 45, which generates the VCO output signal f_{VCO}. The VCO output signal f_{VCO} is both the output signal of the PLL and the feedback returned to the phase comparator 30. The phase comparator 30 and VCO 45 are structured so that the feedback loop is stable when the phase difference between the VCO output signal and the reference signal is zero, in which state the PLL 10 is said to be locked. When the phase difference between the VCO output signal and the reference signal is not zero, feedback operates so as to gradually reduce the difference until the locked state is reached. Once reached, the locked state is maintained.

A typical use of this type of PLL 10 is to generate a signal with a frequency higher than the frequency of the reference signal.

FIG. 2 shows a conventional example of the structure of the VCO 45, comprising a current source Es, a pair of inductors L1, L2, a pair of variable capacitors or varactors C1, C2, and four metal-oxide-semiconductor (MOS) transistors M1, M2, M3, M4, of which M1 and M2 are n-channel transistors and M3 and M4 are p-channel transistors. MOS transistor M1 and inductor L1 are connected in series between a pair of reference nodes n1 and n2 by a wiring path I1. MOS transistor M2 and inductor L2 are connected in series between the same nodes n1, n2 by another wiring path I2. Node n2, the node near MOS transistors M1 and M2, is grounded. Varactors C1 and C2 are connected in series on a wiring path I3, which extends from an internal node N1 between MOS transistor M1 and inductor L1 on wiring path I1 to an internal node N2 between MOS transistor M2 and inductor L2 on wiring path I2. MOS transistors M1 and M2 are cross-coupled, the gate of MOS transistor M1 being connected to node N2 and the gate of MOS transistor M2 being connected to node N1. The control voltage input terminal TVc1 is connected to an internal node N3 between varactors C1 and C2 on wiring path I3.

Varactor C1 is configured as a MOS transistor with its source (S) and drain (D) electrodes connected to node N1 and its gate (G) electrode connected to node N3. The common interconnection of the source and drain electrodes forms one terminal of the capacitor, denoted sd1; the gate electrode forms the other terminal. Varactor C2 is similarly configured as a MOS transistor with its source-drain terminal sd2 connected to node N2 and its gate electrode G connected to node N3. The varactor structure will be shown in more detail presently; suffice it to say at this point that the control voltage applied to node N3 controls the static capacitance of the varactors C1, C2.

The inductors L1, L2 and varactors C1, C2 form an inductance-capacitance (LC) resonant circuit LC1.

The current source Es has one terminal connected to ground and another terminal connected to the gate and drain of MOS transistor M3 and the gate of MOS transistor M4. The sources of these transistors M3, M4 receive a fixed positive potential +V0 from a reference voltage source (not shown). The drain of transistor M4 is connected to node n1.

Transistors M3 and M4 form a current mirror, ensuring that proportional currents flow on the path I4 from +V0 to ground through MOS transistor M3 and the current source Es and the parallel path I5 from +V0 to ground through MOS transistor M4, the LC resonant circuit LC1, and MOS transistors M1 and M2.

The LC resonant circuit LC1 has a peak impedance at a resonant frequency fosc given by the following equation 1, in which L is the sum of the inductances of inductors L1 and L2, Cv is the sum of the capacitances of varactors C1 and C2, and Cp is the total parasitic capacitance, including parasitic wiring capacitance and the gate and drain capacitances of MOS transistors M1 and M2.

fosc=1/(2π√(L×(Cv+Cp))) (1)

This VCO 45 operates differentially. The constant current drawn by the current source Es on path I4 is matched by a proportional current on path I5, which is equal to the sum of the currents on paths I1 and I2. Transistors M1 and M2 switch on and off alternately, causing current to shift back and forth between paths I1 and I2 at the above frequency (fosc) under the amplifying action of the transistors M1, M2, the charging and discharging of the varactors C1, C2, and the inductive kick of the inductors L1, L2. The voltage at node N1 varies sinusoidally as shown in FIG. 3A while the voltage at node N2 varies in a complementary sinusoidal fashion as shown in FIG. 3B. These node voltages are output to a buffer circuit (not shown) that amplifies them to generate the VCO output signal.

Although the VCO output signal itself may be fed back to the phase comparator 30 as shown in FIG. 1, in practice the signals from a plurality of nodes within the VCO are often fed back on a plurality of wiring paths. In FIG. 2, for example, the complementary signals from nodes N1 and N2 may be fed back.

Next, the structure of varactors C1, C2 will be described using a representative MOS varactor Va which is illustrated symbolically in FIG. 4 and in cross section in FIG. 5. MOS varactor Va is a variable capacitor element utilizing the voltage dependency of a MOS capacitor, as will be described below. In the drawings, MOS varactor Va is configured as an n-channel MOS transistor, but a p-channel configuration is also possible.

As shown in FIG. 4, MOS varactor Va has a three-terminal structure with a source terminal S, a gate terminal G, and a drain terminal D. The source and drain terminals S, D, however, are interconnected by a common interconnection sd and supplied through the common interconnection sd with a node voltage Vₛₜ: in the VCO 45 under discussion, Vₛₜ is the voltage at node N1 or N2.

As shown in FIG. 5, MOS varactor Va comprises a silicon substrate 110, a first oxide film 120 formed on the silicon substrate 110, and a thin silicon film 130 formed on the first oxide film 120. The silicon substrate 110, first oxide film 120, and thin silicon film 130 constitute a silicon-on-insulator (SOI) structure 140. The first oxide film 120 is buried under the thin silicon film 130 and is also referred to as a buried oxide film or BOX film.

The thin silicon film 130 is partially occupied by N⁺ diffusion regions 130a, 130b and a P⁻ diffusion region 130c. In this example, the N⁺ diffusion regions 130a, 130b are doped with an n-type impurity such as phosphorus and the P⁻ diffusion region 130c is doped with a p-type impurity such as boron. Additional salicide (CoSi₂) layers 130aa, 130ba are formed on the surfaces of the N⁺ diffusion regions 130a, 130b by deposition of cobalt (Co) on the N⁺ diffusion regions 130a, 130b followed by heat treatment, causing a thermal reaction between the cobalt and the silicon.

N⁺ diffusion region 130a serves as the source electrode and N⁺ diffusion region 130b serves as the drain electrode of the varactor Va. The P⁻ diffusion region 130c, which is the silicon region below the gate electrode, is also referred to as the body region BD.

A source terminal S is formed on the N⁺ diffusion region 130a and a drain terminal D is formed on the N⁺ diffusion region 130b. A second oxide film 150 serving as a gate oxide film is formed on the P⁻ diffusion region 130c, a polysilicon film 160 is formed on the upper surface of the second oxide film 150, and sidewalls 170 are formed on the sides of the polysilicon film 160. A gate terminal G is connected to the polysilicon film 160. The sidewalls 170 are formed of, for example, a silicon nitride (SiN) film or a silicon dioxide (SiO₂) film. A salicide (CoSi₂) layer 160a is formed on the surface of the polysilicon film 160 by deposition of cobalt (Co) on the polysilicon film 160, followed by heat treatment, causing a thermal reaction of the cobalt with the silicon.

Due to the SOI structure of MOS varactor Va, it has a smaller capacitance than a varactor formed on a conventional bulk silicon substrate would have, so a high-performance varactor is obtained. Varactors such as varactor Va are suitable for use in devices that must have low power consumption.

MOS varactor Va has a variable capacitance C that is equal to the sum of the capacitances of the source and drain electrodes with respect to the gate electrode and includes the capacitance Cox of the second oxide film 150, the depletion-region capacitance Cd of the depleted channel layer formed at the surface of the P⁻ diffusion region 130c below the second oxide film 150, the capacitance CBOX of the first oxide film 120, the parasitic or fringing gate-source capacitance Cfs, and the fringing gate-drain capacitance Cfd. Of these capacitance elements, Cox, Cd, and CBOX are in series, Cfs and Cfd are in parallel with them, Cox, CBOX, Cfs, and Cfd are constant, and Cd varies depending on the control voltage Vc1 applied to the gate terminal G, which therefore determines the total capacitance of the MOS varactor Va.

FIG. 6 is a graph illustrating voltage-capacitance curves of this conventional MOS varactor Va, where the horizontal axis represents the control voltage Vc1 in volts (V) and the vertical axis represents the variable capacitance C in farads (F) in exponential notation. The capacitance varies in the range from about 0.21 pF (0.21 picofarads) to about 0.45 pF. The solid line and white squares represent the voltage-capacitance curve of a discrete MOS varactor Va; the dotted line and black squares represent the voltage-capacitance curve of the MOS varactor Va when incorporated in an integrated circuit. FIG. 6 illustrates the curves of an n-channel MOS varactor Va; for a p-channel MOS varactor Va, the voltage dependence is reversed.

Next, the oscillation frequency range of the VCO 45 will be described with reference to FIG. 7. FIG. 7 illustrates the voltage-frequency curve of the VCO 45 when the direct-current (DC) component of the voltage at nodes N1 and N2 is 0.3 V, the sum of the inductances of inductors L1 and L2 is 2.28 nH (2.28 nanohenries), and the sum of the parasitic capacitances of transistors M1 and M2 is 1.5 pF. In FIG. 7, the horizontal axis represents the control voltage Vc1 applied to the gate electrodes of the varactors C1, C2 and the vertical axis represents the oscillation frequency (freq) of the VCO 45. As shown in FIG. 7, the oscillation frequency of the VCO 45 varies depending on the control voltage Vc1.

The PLL 10 in FIG. 1 must lock at different frequencies for devices executing different applications. For some applications there is a specified range of frequencies: for example, the range from 2.4 GHz to 2.5 GHz for Zigbee and Bluetooth applications. The VCO 45 in FIG. 1 should ideally be capable of covering the entire specified frequency range.

FIG. 7 illustrates a case in which this condition is not met. Double-headed arrow A1 indicates the frequency range specified for the applications mentioned above (2.4-2.5 GHz). Double-headed arrow A2 indicates the variable range of the control voltage Vc1 applied to the gate electrodes of the varactors C1, C2 (0.1-0.9 V). Double-headed arrow A3 indicates the oscillation frequency range of the VCO 45 when the control voltage Vc1 varies in this range. Although arrows A1 and A3 have approximately the same length, arrow A3 extends from 2.46 GHz to 2.55 GHz, so the variable frequency range of the VCO 45 is offset considerably from the application frequency range from 2.40 GHz to 2.50 GHz.

When the oscillation frequency range of the VCO 45 is offset from the specified application frequency range, the manufacturer may try to correct the offset by adjusting the variable range of the control voltage Vc1. In the example in FIG. 7, however, this would require moving the left tip of arrow A2 to the negative side of the zero point on the control voltage scale, which may be difficult or impossible. Furthermore, even if the variable range of the control voltage Vc1 could be adjusted to include negative voltages, the voltage-frequency curve of the VCO 45 would remain unchanged.

The greatest margin of tolerance for manufacturing variations is obtained when the oscillation frequency range of the VCO 45 is centered at the specified application range. In FIG. 7, however, the application range (arrow A1) is centered at 2.45 GHz, while the oscillation frequency range of the VCO 45 is centered at about 2.47 GHz. This center-frequency offset cannot be corrected by adjusting the control voltage Vc1.

It will be appreciated from FIG. 7 that the fixed voltage-frequency curve of the VCO 45 makes it difficult to adjust the control voltage range to meet the needs of an application, and therefore restricts the applications in which the VCO 45 can be used.

When the oscillation frequency range of the VCO 45 is offset from the specified application frequency range, therefore, the manufacturer may try to redesign the VCO 45 by modifying the sizes of varactors C1, C2 and inductors L1, L2 to make the oscillation frequency range of the VCO 45 cover the application frequency range. Such redesign work, however, involves considerable time, effort, and expense.

When the voltage-frequency curve of the VCO 45 is fixed, accordingly, there is no easy and efficient way to adjust the control voltage range so that the oscillation frequency range covers the application frequency range accurately.

The reason why the voltage-frequency curve is fixed in the conventional VCO is that the voltage-capacitance curves of the varactors used in the VCO are fixed.

After studying this problem, the inventor concluded that if varactors having a variable voltage-capacitance curve were used in the VCO, it would be possible to adjust the oscillation frequency range of the VCO to fit a specified application range accurately by changing the voltage-frequency curve of the VCO.

The inventor also concluded that it would be particularly desirable to be able to shift the voltage-capacitance curve parallel to the voltage axis without changing the shape of the curve.

These conclusions led the inventor to try modifying the varactor so that the potential distribution in its body region could be changed, in the hope that this might shift the voltage-capacitance curve parallel to the voltage axis without changing the shape of the curve.

### SUMMARY OF THE INVENTION

A VCO according to the present invention includes a first reference node receiving a first current and a second reference node receiving a first fixed potential. The VCO also includes first and second inductors, a first MOS transistor, and a second MOS transistor cross-coupled with the first MOS transistor. A first internal node is coupled through the first inductor to the first reference node, and through the first MOS transistor to the second reference node. A second internal node is coupled through the second inductor to the first reference node, and through the second MOS transistor to the second reference node.

The VCO further includes a third internal node, a first MOS varactor, and a second MOS varactor. The third internal node receives a control voltage signal. The first MOS varactor has a pair of impurity diffusion regions and an electrode. The pair of impurity diffusion regions are electrically connected to the first internal node and the electrode is electrically connected to the third internal node; alternatively, the pair of impurity diffusion regions are electrically connected to the third internal node and the electrode is electrically connected to the first internal node. The second MOS varactor has a similar structure with the pair of impurity diffusion regions electrically connected to the second (alternatively, the third) internal node and the electrode electrically connected to the third (alternatively, the second) internal node.

Each of the first and second MOS varactors includes a silicon layer in which the pair of impurity diffusion regions are formed, an insulating film separating the electrode from the silicon layer, and a body region disposed in the silicon layer. The body region includes a main body region and a body terminal region. The main body region is disposed below the electrode and between the impurity diffusion regions. The body terminal region is electrically connected to an input terminal that receives an adjustment voltage signal.

The adjustment voltage signal adjusts the relationship between the control voltage signal and the capacitances of the first and second MOS varactors. This relationship can be plotted as a curve in a two-dimensional Cartesian coordinate system with a voltage axis and a capacitance axis, the curve describing how the capacitance of the varactor varies in response to the control voltage applied to the third node. When the voltage applied to the body terminal region is changed, the potential distribution in the body region changes in a way that shifts the voltage-capacitance curve without changing the shape of the curve. The adjustment voltage can be adjusted to center the voltage-capacitance curve within the variable range of the control voltage signal, so that the maximum variable capacitance range is obtained, thereby maximizing the oscillating frequency range and accuracy of the VCO.

The adjustment voltage applied to the body terminal region also provides a simple and accurate way to tailor the VCO to the specifications of a particular application.

Since the shape of the voltage-capacitance curve is maintained during these adjustments, it is not necessary to make repeated measurements of the curve; sampling data taken before the adjustment begins can be used throughout the adjustment process.

### BRIEF DESCRIPTION OF THE DRAWINGS

In the attached drawings:

FIG. 1 is a more general block diagram of a PLL;

FIG. 2 is a circuit diagram of a conventional VCO;

FIGS. 3A and 3B illustrate voltage signals output from nodes N1 and N2 in FIG. 2;

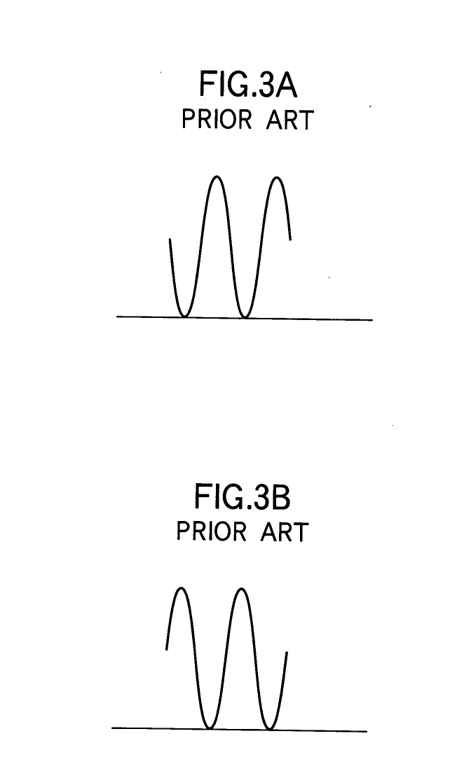

FIG. 4 symbolically illustrates the structure of the varactors in FIG. 2;

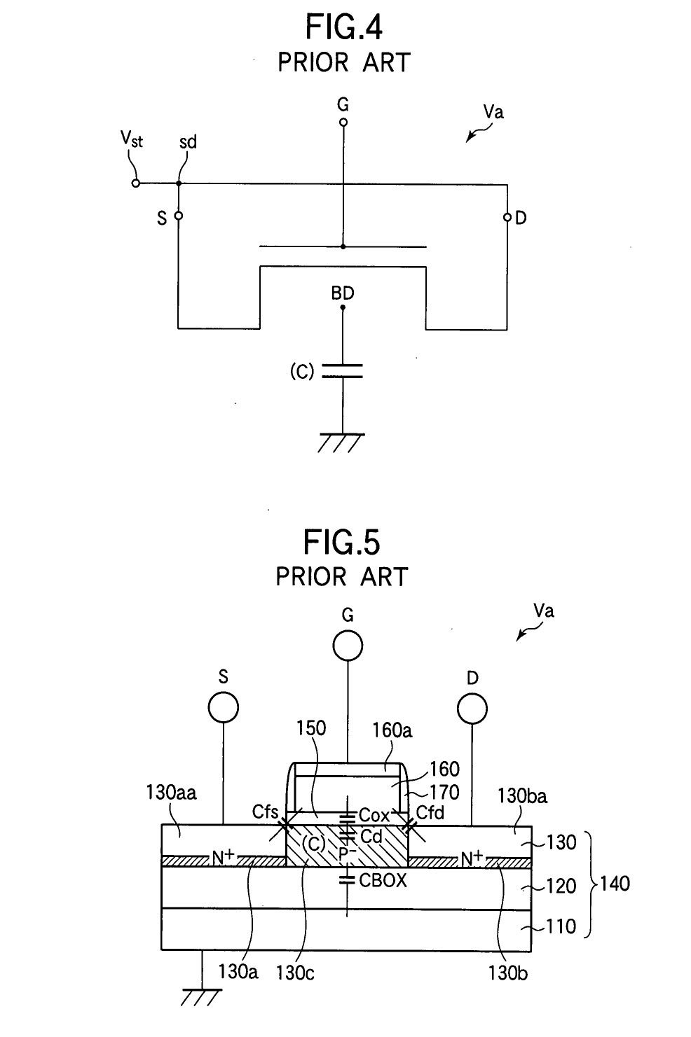

FIG. 5 is a sectional view schematically illustrating the structure of the varactors in FIG. 2;

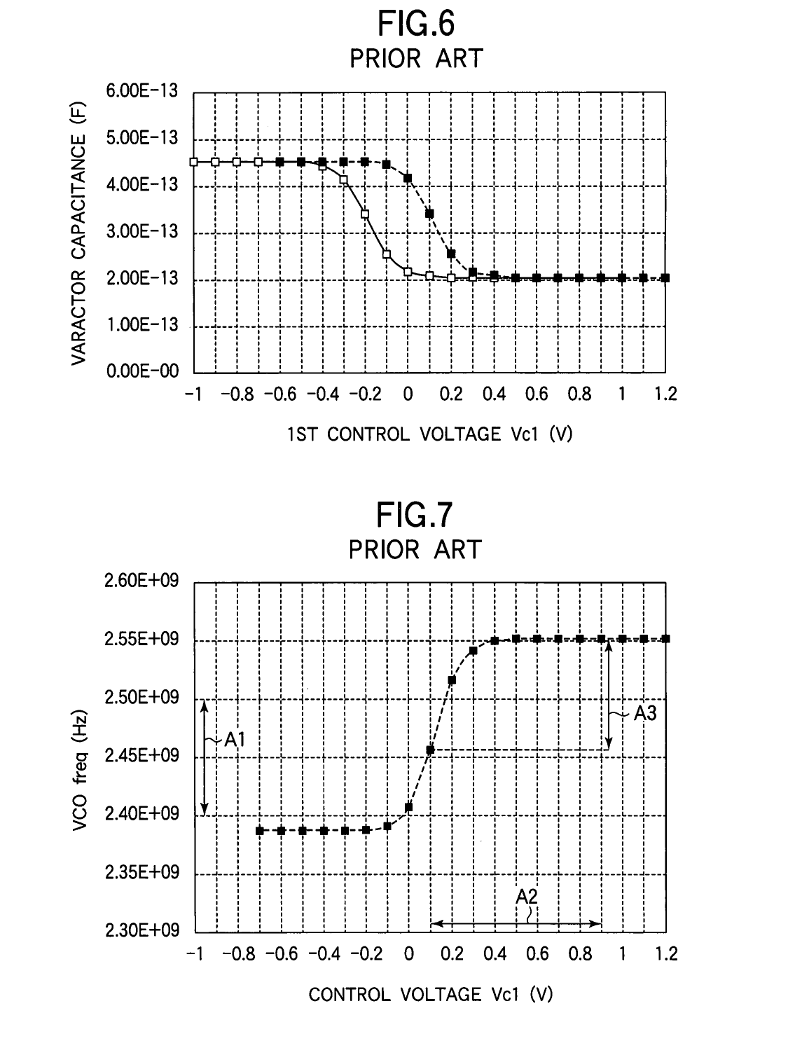

FIG. 6 is a graph illustrating voltage-capacitance curves of the varactors in the VCO in FIG. 2;

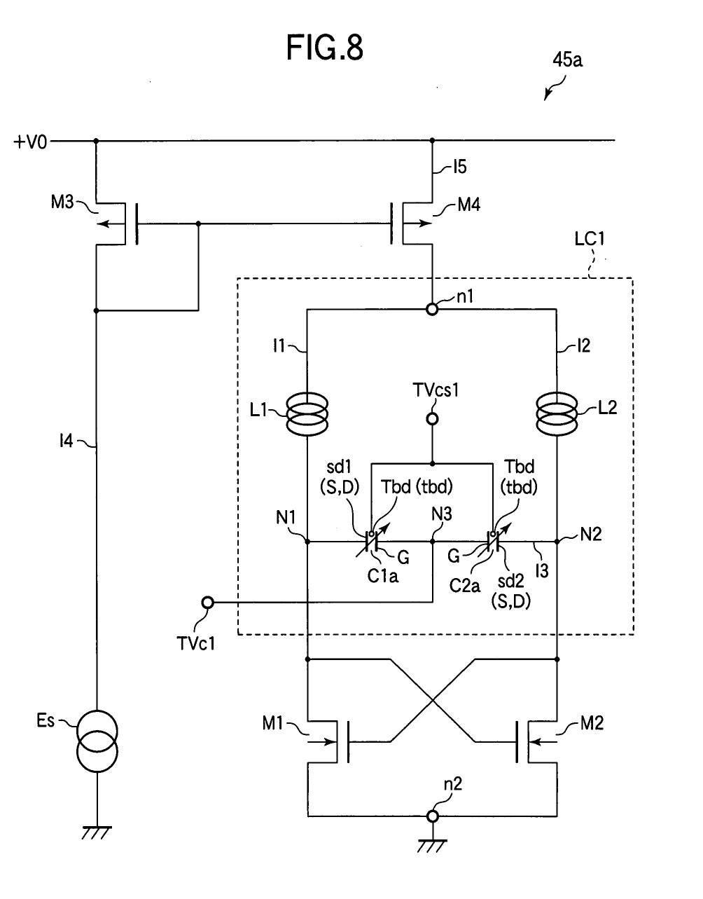

FIG. 7 is a graph illustrating the voltage-frequency curve of the VCO in FIG. 2;

FIG. 8 is a circuit diagram of a VCO embodying the invention;

FIG. 9 symbolically illustrates the structure of the varactors in FIG. 8;

FIG. 10 is a sectional view schematically illustrating the structure of the varactors in FIG. 8;

FIG. 11 is a top plan view illustrating the physical structure of the varactors in FIG. 8;

FIGS. 12 and 13 are sectional views illustrating the physical structure of the varactors in FIG. 8;

FIGS. 14A, 15A, 16A, 17A, 18A, 19A, 20A, 21A, 22A, 23A, 24A, 25A, 26A, and 27A are sectional views corresponding to FIG. 12, illustrating successive steps in the fabrication of the varactors in FIG. 8;

FIGS. 14B, 15B, 16B, 17B, 18B, 19B, 20B, 21B, 22B, 23B, 24B, 25B, 26B, and 27B are sectional views corresponding to FIG. 13, likewise illustrating the successive steps in the fabrication of the varactors in FIG. 8;

FIG. 28 is a graph illustrating voltage-capacitance curves of the varactors in the VCO in FIG. 8;

FIG. 29 is a graph illustrating voltage-frequency curves of the VCO in FIG. 8;

FIG. 30 is a circuit diagram illustrating a modified form of the VCO in FIG. 8, also embodying the invention;

FIG. 31 is a graph illustrating voltage-capacitance curves in the VCO in FIG. 30;

FIG. 32 is a graph illustrating voltage-frequency curves of the VCO in FIG. 30; and

FIG. 33 is a block diagram of a PLL using a VCO embodying the invention.

### DETAILED DESCRIPTION OF THE INVENTION

A novel VCO embodying the invention will now be described with reference to the attached drawings, in which like elements are indicated by like reference characters. The drawings are only intended to provide an understanding of the invention; they do not necessarily show the exact sizes, shapes, or positional relationships of the constituent elements of the VCO, and do not limit the scope of the invention.

### Structure of the VCO

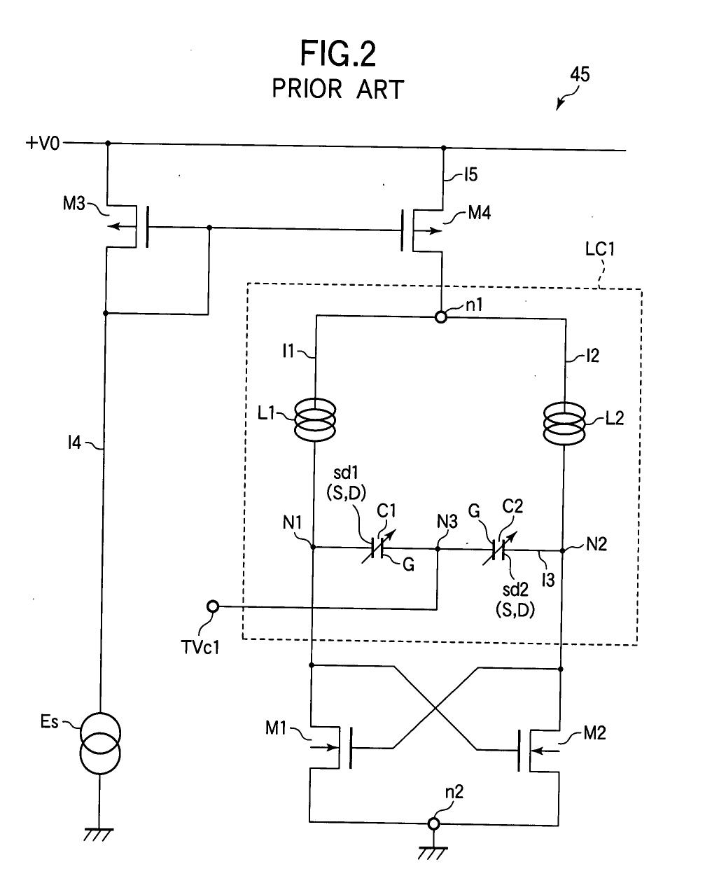

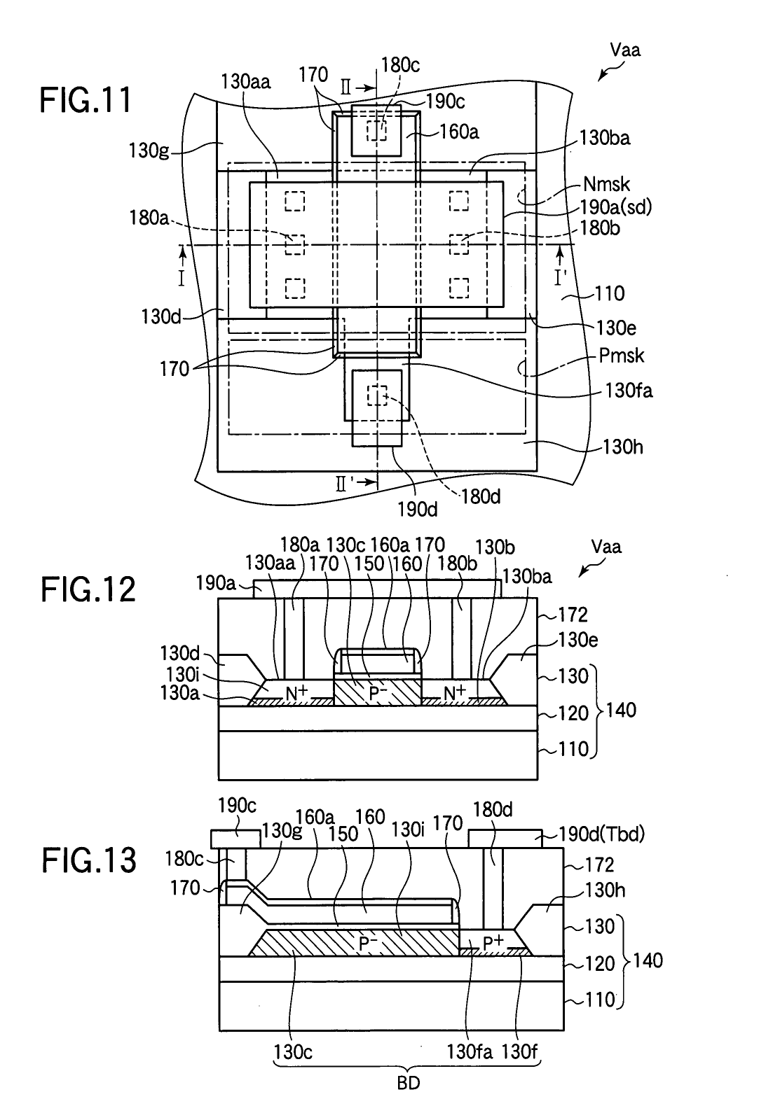

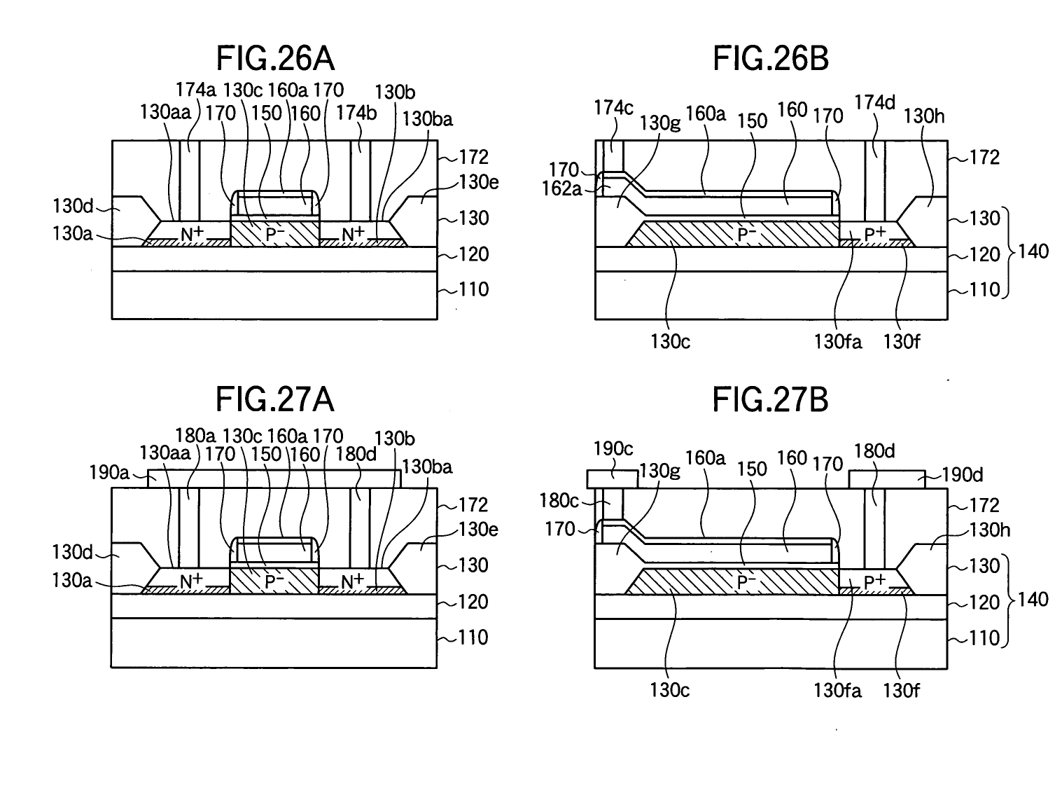

Referring to FIG. 8, the novel VCO 45a differs from the conventional VCO shown in FIG. 2 by using varactors C1a, C2a with body terminals Tbd connected to an adjustment voltage input terminal or control shifting voltage input terminal TVcs1. Like the conventional varactors, the varactors C1a, C2a with body terminals are capacitors with static capacitance values that can be controlled by a voltage signal applied to their gate electrodes G. The body terminals Tbd are disposed on one of the major surfaces of each capacitor (referred to below as the top surface of the capacitor), and are connected to a body terminal region (tbd) in the body region of the capacitor (the body region will be denoted BD in subsequent drawings). The voltage signal applied to terminal TVcs1 is an adjustment voltage Vcs1 that shifts the voltage-capacitance curve of the varactor as illustrated later (FIG. 28). The adjustment voltage Vcs1 is generated externally and may have a negative value.

Both the control voltage Vc1 and the adjustment voltage Vcs1 alter the capacitance of the varactors. The control voltage Vc1, however, is applied to one of the main electrodes of the varactor (the gate electrode, in this embodiment), while the adjustment voltage Vcs1 is applied to the body terminal.

In other respects, the novel VCO 45a is identical to the conventional VCO 45 shown in FIG. 2; a detailed enumeration and description of the circuit elements other than the varactors C1a, C2a and their interconnections will be omitted since these circuit elements have already been described in the discussion of the related art.

The basic operation of the novel VCO 45a is the same as in the conventional VCO 45. Current generated by a current source Es is drawn through a transistor M3 and mirrored by a transistor M4, and the mirroring current is supplied through an LC resonant circuit LC1 to cross-coupled transistors M1, M2. This causes cross-coupled transistors M1, M2 to turn on and off alternately and repeatedly, thereby generating complementary oscillating signals (VCO output signals) at nodes N1 and N2.

### Structure of Varactor with Body Terminal

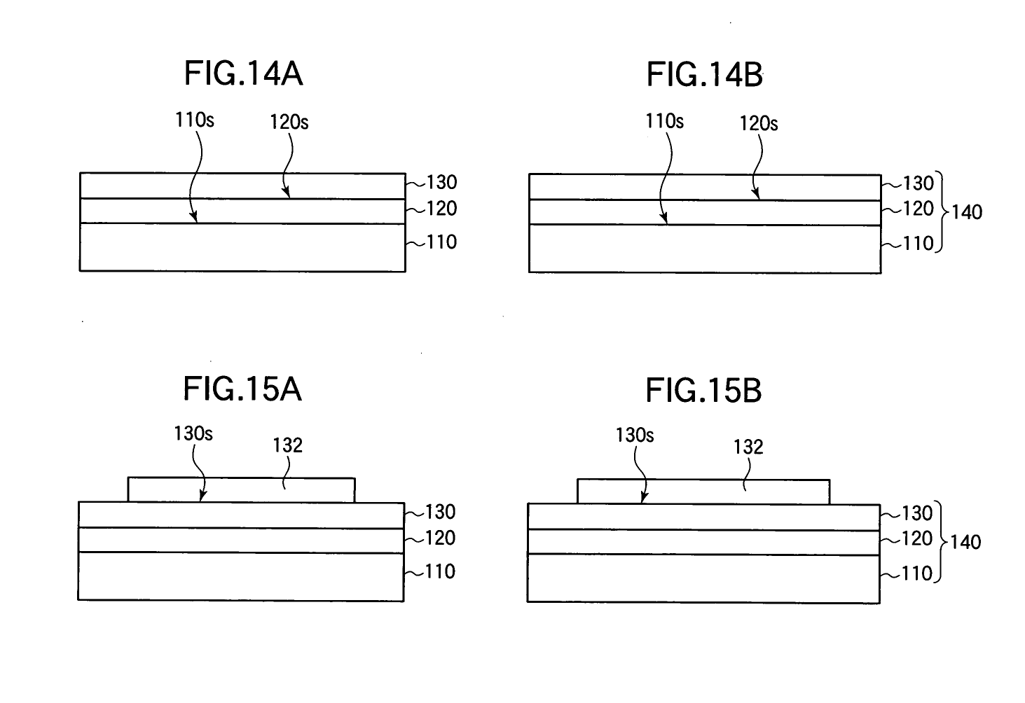

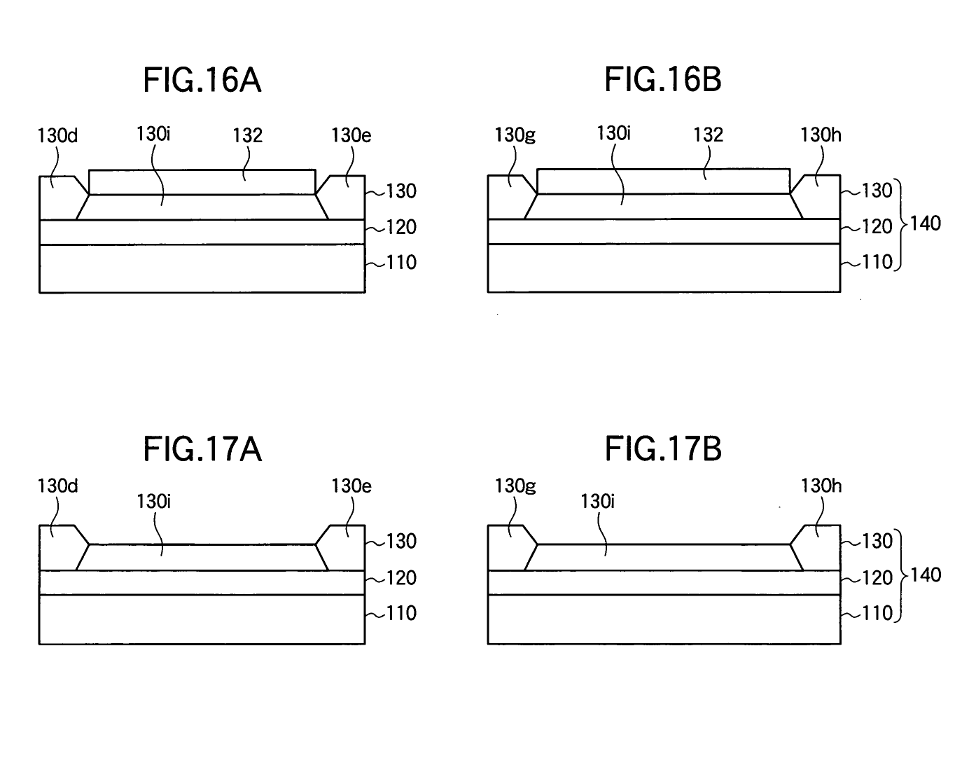

The structure of the varactors C1a, C2a with body terminals will be described using a representative MOS varactor Vaa illustrated symbolically in FIG. 9 and in a schematic cross section in FIG. 10.

As shown in FIG. 9, the novel MOS varactor Vaa has an electrical structure substantially similar to that of the conventional MOS varactor Va, with source (S), gate (G), and drain (D) terminals, a body region (BD), and a source-drain interconnection (sd), but also has a body terminal Tbd electrically connected to a body terminal region tbd, which forms part of the body region BD.

As shown in FIG. 10, the basic structure of the novel varactor Vaa is also similar to that of the conventional MOS varactor Va. A silicon substrate 110, a first oxide film or buried oxide film 120, and a thin silicon layer 130 form an SOI structure 140. N⁺ source and drain diffusion regions 130a, 130b with salicide layers 130aa, 130ba are formed in the thin silicon layer 130, a P⁻ diffusion region 130c is disposed between the N⁺ source and drain diffusion regions 130a, 130b. The gate electrode is a polysilicon film 160 with a salicide layer 160a and sidewalls 170. The body terminal region tbd is not visible in this cross section, but is represented by the line joining the body terminal Tbd to the P⁻ diffusion region 130c, which forms the main part of the body region BD.

The body terminal Tbd is actually disposed on the top surface of the varactor, but is shown in perspective in FIGS. 9 and 10 so as not to obscure the gate terminal G.

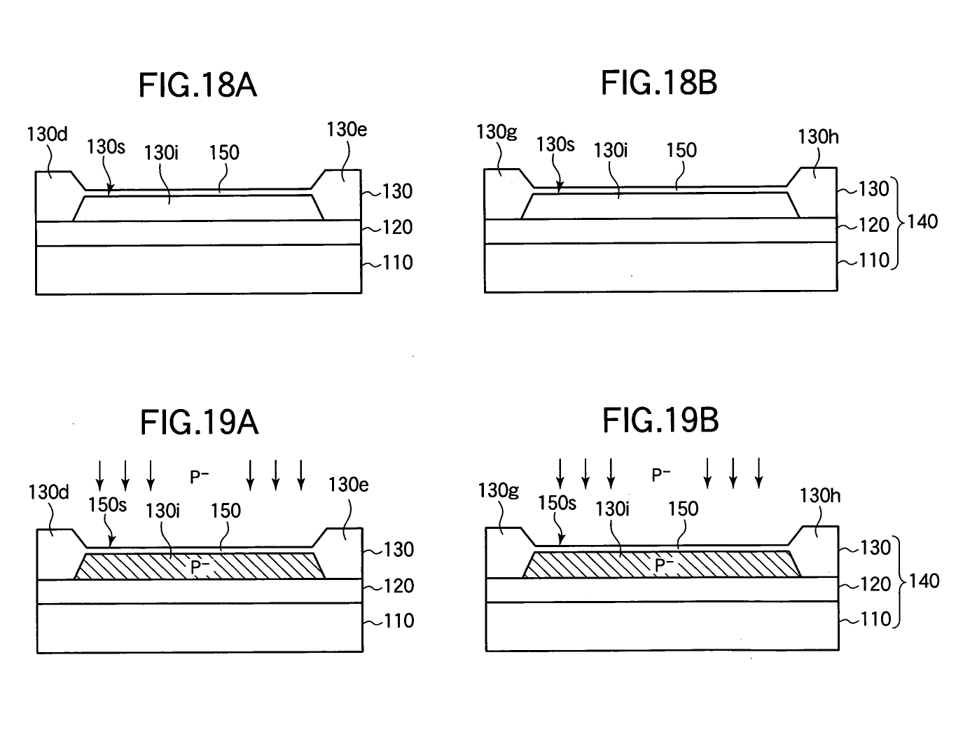

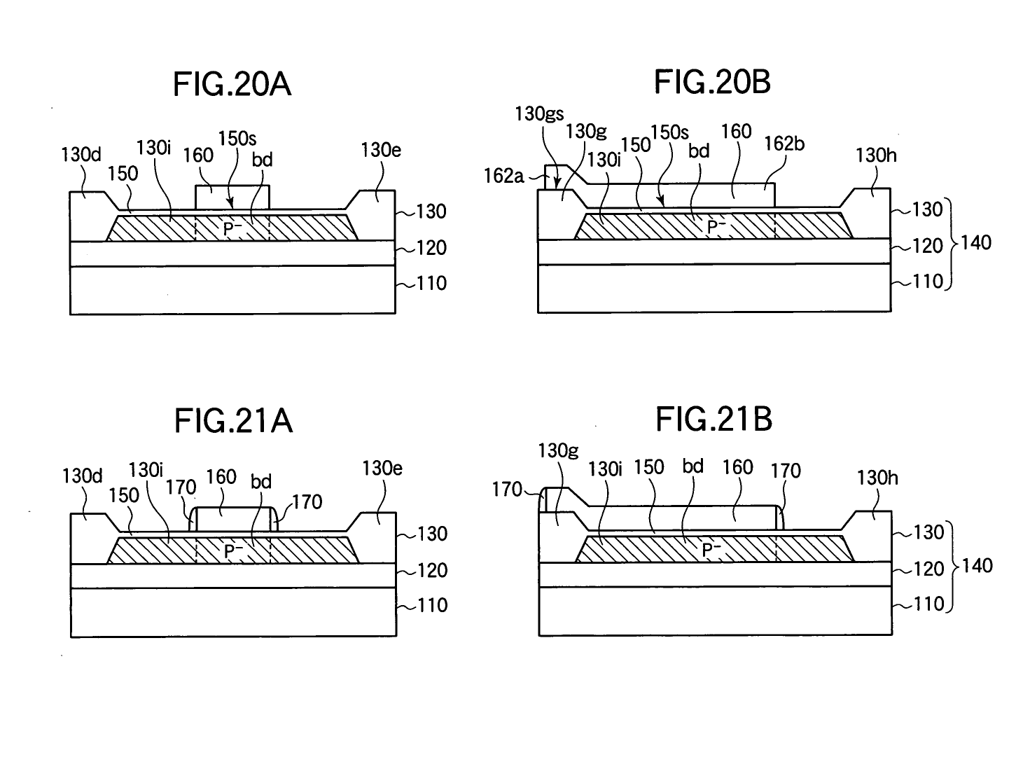

Next, the physical structure of the varactors C1a, C2a with body terminals will be described in detail with reference to FIGS. 11 to 13, which show the novel varactor Vaa in a top plan view and two sectional views. FIG. 12 is a sectional view through line I-I′ in FIG. 11; FIG. 13 is a sectional view through line II-II″ in FIG. 11.

Besides the N⁺ diffusion regions 130a, 130b, and P⁻ diffusion region 130c, the varactor structure includes field oxide regions 130d, 130e, a P⁺ diffusion region 130f, and further field oxide regions 130g, 130h. The field oxide regions 130d, 130e, 130g, 130h are silicon dioxide (SiO₂) regions formed by oxidizing the thin silicon film 130. The source N⁺ diffusion region 130a is disposed between the P⁻ main body diffusion region 130c and field oxide region 130d. The drain N⁺ diffusion region 130b is disposed between the P⁻ main body diffusion region 130c and field oxide region 130e. Field oxide regions 130g and 130h are disposed on opposite sides of the diffusion regions 130a, 130b, 130c. The P⁺ diffusion region 130f is an extension of the P⁻ main body diffusion region 130c and is surrounded on three sides by field oxide region 130h. The body terminal region tbd includes the P⁺ diffusion region 130f and a salicide layer 130fa formed thereupon.

A thin silicon oxide (SiO₂) film 150 serving as a gate oxide film is formed on the P⁻ main body diffusion region 130c. The silicon film 160, salicide layer 160a, and sidewalls forming the gate electrode structure are disposed partly on this second silicon oxide film 150 and partly on field oxide region 130g, but do not cover the P⁺ body terminal diffusion region 130f and its salicide layer 130fa. The sidewalls 170 are films of, for example, silicon nitride (SiN) or silicon dioxide (SiO₂).

The P⁺ body terminal diffusion region 130f is doped at a higher concentration than the P⁻ main body diffusion region 130c. A p-type impurity (e.g., boron) is implanted first at a comparatively low concentration into the entire thin silicon layer 130, then at a comparatively high concentration through a P⁺ mask opening Pmsk (a rectangular area shown enclosed by a dash-dot line in FIG. 11). An n-type impurity (e.g., phosphorus) is implanted at a comparatively high concentration through an N⁺ mask opening Nmsk (another rectangular area shown enclosed by a dash-dot line). The P⁺ and N⁺ implantations are performed after the gate electrode structure has been formed, so as to leave the main body region 130c below the gate electrode structure as a P⁻ region. The salicide layers 130aa, 130ba, 130fa, 160a are formed by deposition of cobalt on the surfaces of the N⁺ diffusion regions 130a, 130b, P⁺ diffusion region 130f, and polysilicon film 160, followed by heat treatment, causing the cobalt to react thermally with the silicon.

The above parts of the varactor are covered by a dielectric film 172 of silicon dioxide (SiO₂) with holes positioned over the salicided regions. A plug contact 180a is formed in a hole leading to the source salicide layer 130aa. Another plug contact 180b is formed in a hole leading to the drain salicide layer 130ba. A metal terminal 190a is formed on the surface of the dielectric film 172, making contact with plug contacts 180a and 180b. Plug contacts 180a and 180b electrically connect the metal terminal 190a to the N⁺ diffusion regions 130a, 130b, that is, to the source and drain electrodes of the varactor Vaa. To ensure a good electrical connection, there may be more than one plug contact 180a and more than one plug contact 180b, as shown in FIG. 11. Metal terminal 190a is the common interconnection (sd) that interconnects the source and drain electrodes.

A contact 180c formed in another hole leads from the gate electrode salicide layer 160a to another metal terminal 190c disposed on the surface of the dielectric film 172. This metal terminal 190c is the gate terminal of the varactor. A plug contact 180d formed in yet another hole leads from the body terminal salicide layer 130fa to yet another metal terminal 190d disposed on the surface of the dielectric film 172. Metal terminal 190d is the body terminal Tbd of the varactor. The contacts 180a to 180d are formed of, for example, tungsten (W), and the metal terminals 190a to 190d are formed of, for example, aluminum (Al).

The adjustment voltage applied to the body terminal Tbd controls the potential in the P⁻ main body diffusion region 130c located below the gate electrode. The body terminal Tbd is electrically isolated from the gate terminal G, source terminal S, and drain terminal D, and the adjustment voltage Vcs1 can be applied independently of the gate, source, and drain voltages. Due to the presence of the body terminal Tbd and body terminal region tbd, MOS varactor Vaa has additional body-gate, body-source, and body-drain parasitic capacitances that slightly increase the total varactor capacitance.

In the drawings, the novel MOS varactor Vaa is configured as an n-channel MOS transistor, but it may also be configured as a p-channel MOS transistor. A p-channel MOS varactor has characteristics reverse to those of an n-channel MOS varactor.

### Varactor Fabrication Process

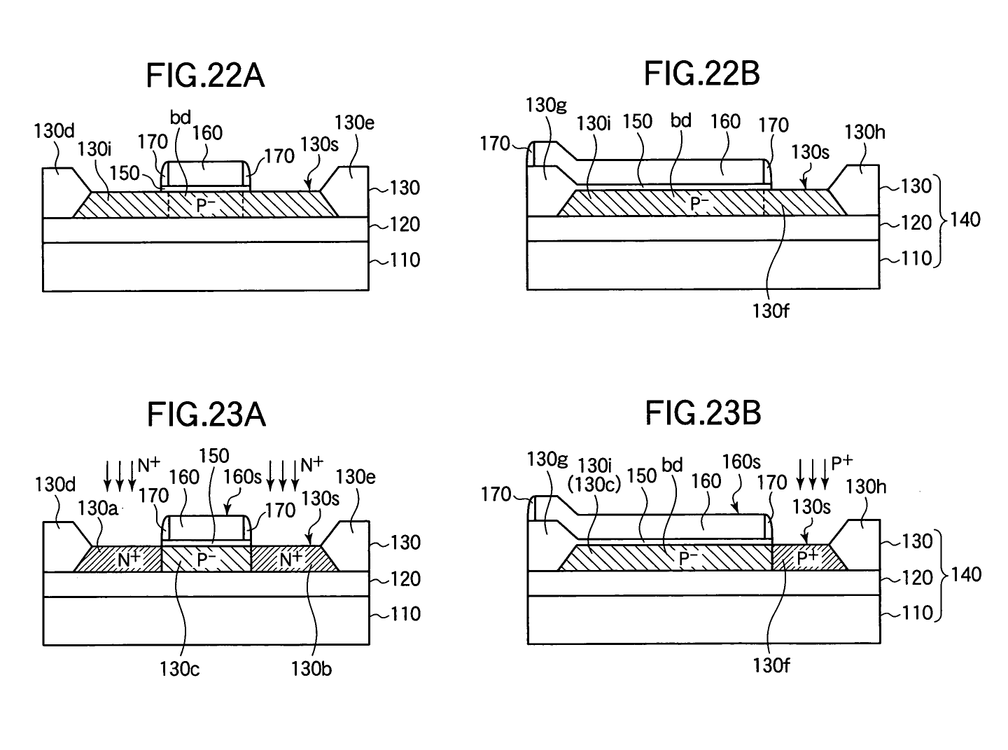

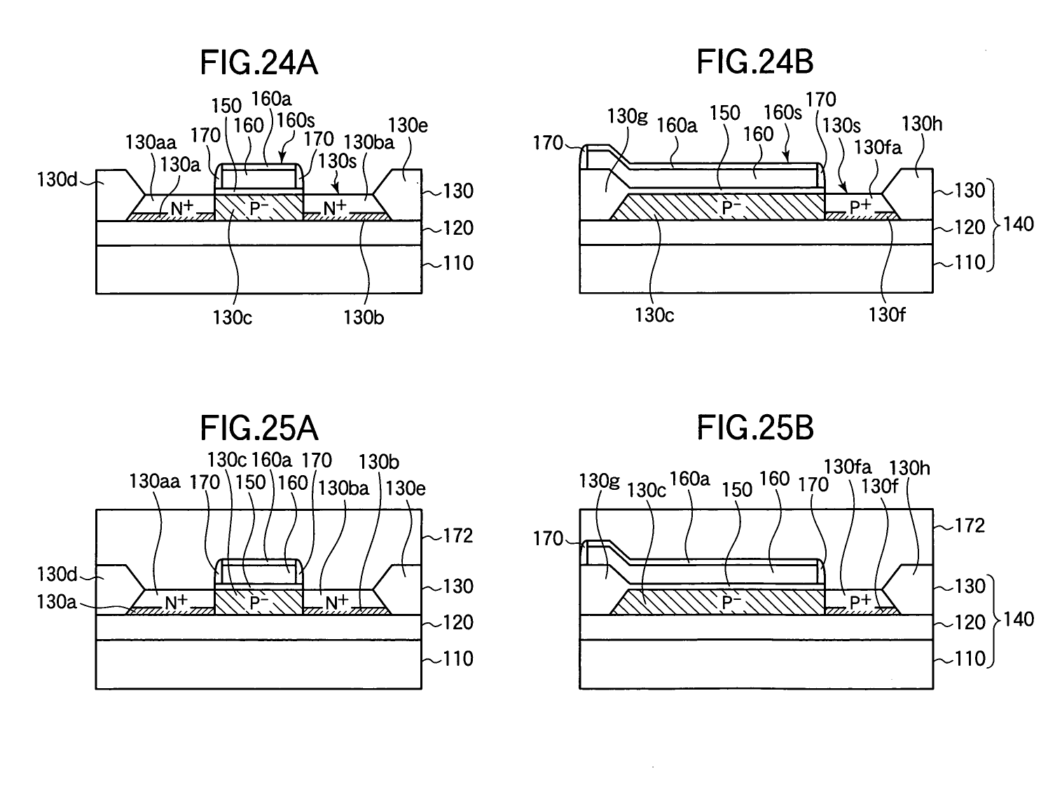

A fabrication process for the novel varactor Vaa with a body terminal will be described with reference to FIGS. 14A and 14B to FIGS. 27A and 27B, which show sectional views of the varactor structure obtained at each process step. The drawings numbered with an ‘A’ suffix are sectional views through line I-I′ in FIG. 11; the drawings numbered with a ‘B’ suffix are sectional views through line II-II′ in FIG. 11.

(1) SOI Formation

In this step, a wafer with an SOI structure 140 including a silicon substrate 110, a first oxide film 120, and a thin silicon film 130 is obtained as shown in FIGS. 14A and 14B.

First a silicon substrate 110 with a thickness of, for example, about 0.1 μm to 0.2 μm is prepared.

Next, the first oxide film 120 is formed on the entire top surface 110s of the silicon substrate 110. The first oxide film 120 may be formed by any suitable method: for example, an oxide film one hundred to two hundred nanometers (100-200 nm) thick may be formed by chemical vapor deposition (CVD) and chemical mechanical polishing (CMP).

The thin silicon film 130 is then formed on the surface 120s of the first oxide film 120. Any suitable method may be used: for example, a thin silicon film 130 with a thickness of about 50 nm may be formed by a well-known bonding and cleaving technique. The first oxide film 120 then becomes a buried oxide film.

(2) Oxidation Mask Formation

An oxidation mask is formed selectively on the surface 130s of the thin silicon film 130 to obtain the structure in FIGS. 15A and 15B.

The oxidation mask is a silicon nitride (SiN) film 132 covering the regions 130a, 130b, 130c, 130f (shown in FIGS. 12 and 13) of the thin silicon film 130 that will become the source and drain electrodes of the varactor and the body region BD, including the body terminal region tbd. The thickness of the silicon nitride film 132 is, for example, approximately 10 nm. The silicon nitride film 132 may be formed by well-known photolithography and etching processes.

The silicon nitride film 132 functions as an oxidation mask by preventing oxidation of the covered regions when the thin silicon film 130 is oxidized in next step.

(3) Field Oxidation

Next, the part of the thin silicon film 130 that is not covered by the silicon nitride film 132 is oxidized to obtain the structure shown in FIGS. 16A and 16B. In this well-known oxidation process, silicon reacts with oxygen to form silicon dioxide (SiO₂) in the field oxide regions 130d, 130e, 130g, 130h. A non-oxidized region 130i is left below the silicon nitride film 132. As a result of the oxidation process, the thickness of the field oxide regions 130d, 130e, 130g, 130h increases as shown in the drawings.

The non-oxidized region 130i is a remaining thin silicon film that will be doped with impurities in subsequent ion implantation and annealing steps.

(4) Oxidation Mask Removal

Next, the oxidation mask (the silicon nitride film 132) is removed, by etching, for example, from the surface 130s of the thin silicon film 130 to obtain the structure shown in FIGS. 17A and 17B.

(5) Gate Oxide Film Formation

Next, a gate oxide film is formed on the surface 130s of the remaining thin silicon film 130i to obtain the structure shown in FIGS. 18A and 18B.

In this step, a second oxide film 150 of silicon dioxide (SiO₂) with a thickness of, for example, approximately 2.5 nm is formed on the surface 130s of the remaining thin silicon film 130i to serve as the gate oxide film. The second oxide film 150 may be formed by any suitable method: for example, CVD followed by CMP. The second oxide film 150 will be partially removed in a subsequent step to leave only the part below the gate electrode.

(6) Impurity Ion Implantation for Threshold Adjustment

Next, impurity ions are implanted into the entire remaining thin silicon film 130i to obtain the structure shown in FIGS. 19A and 19B. The purpose of this ion implantation is to adjust the gate threshold voltage. For a varactor with source and drain electrodes of a first conductive type, the implanted ions are of a second conductive type. For the n-channel MOS varactor Vaa of the present embodiment, for example, boron difluoride ions (BF₂) may be implanted into the entire remaining thin silicon film 130i at a dose of 1×10¹² cm⁻² to 3×10 cm⁻². The symbol P⁻ is used in the drawings to indicate this comparatively low concentration of ions of a p-type impurity.

Next, an annealing process is performed to diffuse the implanted ions throughout the remaining thin silicon film 130i so that it becomes a P⁻ diffusion region as indicated in FIGS. 19A and 19B.

For a p-channel MOS varactor, the ion implantation step is identical to the above except that an impurity of the opposite conductive type (an n-type impurity such as phosphorus, for example) is used.

(7) Gate Electrode Formation

Next, a polysilicon film 160 is formed on the surface 150s of the second oxide film 150 and part of the surface 130gs of field oxide region 130g to obtain the structure shown in FIGS. 20A and 20B. The polysilicon film 160 functions as the gate electrode.

The polysilicon film 160 is approximately 100 nm thick and overlies a region bd in the remaining thin silicon film 130i that will become part of the body region BD indicated in FIG. 13. The polysilicon film 160 does not cover the region 130f that will become the body terminal region. The polysilicon film 160 may be formed by any suitable method: for example, by photolithography and etching.

The polysilicon film 160 is formed as a stripe having a predetermined length and a predetermined width. The part bd of the remaining thin silicon film 130i disposed below the polysilicon film 160 will become the main part of the body BD of the varactor; the shape of the polysilicon film 160 defines the shape of the varactor body. The long edges of the polysilicon film 160, extending in the gate width direction, are positioned to obtain the desired body size. The short edges of the polysilicon film 160, extending in the gate length direction, are positioned so that the polysilicon film 160 extends onto field oxide region 130g in one direction and over the second oxide film 150 toward field oxide region 130h in the other direction. The short edge at which the polysilicon film 160 terminates over the second oxide film 150 (the right edge of the polysilicon film 160 in FIG. 20B) is distanced from field oxide region 130h in order to leave space for forming the body terminal region tbd. The part 162a of the polysilicon film 160 that covers field oxide region 130h serves as an interconnecting lead for conducting charge between the gate electrode and the gate terminal G. The part 162b of the polysilicon film 160 that covers the second oxide film 150 functions as the gate electrode.

(8) Sidewall Formation

Next, sidewalls 170 are formed on the sides of the polysilicon film 160 to obtain the structure shown in FIGS. 21A and 21B. The sidewalls 170 may be formed by any suitable method: for example, by CVD and etching. The sidewalls 170 may be formed as nitride films (SiN films) or oxide films (SiO₂ films).

The purposes of forming the sidewalls 170 are as follows. First, when impurity ions are implanted in later steps, the sidewalls 170 function as part of the ion-implantation mask that prevents the impurity from being implanted into the gate electrode (part 162b of the polysilicon film 160). Second, when salicide layers are formed in a subsequent step, the sidewalls 170 prevent short circuits between the gate electrode and the source and drain electrodes.

(9) Oxide Film Removal

Next, the part of the second oxide film 150 exposed on the surface 130s of the remaining thin silicon film 130i, that is, the part not covered by the polysilicon film 160 and sidewalls 170, is removed to obtain the structure shown in FIGS. 22A and 22B.

(10) Source, Drain, and Body Terminal Ion Implantation

Next, impurity ions of the first conductive type (the n-type in this exemplary varactor) are implanted into the regions 130a, 130b that will become the source and drain electrodes in the remaining thin silicon film, and impurity ions of the second conductive type (p-type) are implanted into the region 130f that will become the body terminal region tbd in the remaining thin silicon film, thereby obtaining the structure shown in FIGS. 23A and 23B.

First, an ion-implantation mask such as a patterned silicon nitride film approximately 10 nm thick (not shown) is formed on the surface 160s of the polysilicon film 160. The ion-implantation mask may be formed by, for example, photolithography and etching.

Next, an N⁺ mask (not shown) is formed on the SOI structure 140. The N⁺ mask has a rectangular opening Nmsk (indicated by a dash-dot line in FIG. 11) above the regions 130a, 130b that will become the source and drain electrodes in the remaining thin silicon film.

Impurity ions of the first conductive type are then implanted through the opening Nmsk in the N⁺ mask into these regions 130a, 130b to form the source and drain electrodes. For example, phosphorus ions (P) may be implanted at a dose of 1×10¹⁵ cm⁻² to 5×10¹⁵ cm⁻². The symbol N⁺ is used in FIG. 23A to indicate this comparatively high concentration of ions of an n-type impurity. The ion-implantation mask (nitride film) on the surface 160s of the polysilicon film 160 and the sidewalls 170 on the sides of the polysilicon film 160 ensure that the impurity ions are implanted only into the desired regions 130a, 130b and not into the polysilicon film 160 or the region bd below the polysilicon film 160 that will become part of the body region BD of the varactor.

Next, the above ion-implantation mask and N⁺ mask are removed and a P⁺ mask (not shown) is formed on the SOI structure 140. The P⁺ mask has an opening Pmsk (indicated by a dash-dot line in FIG. 11) above the region 130f that will become the body terminal region tbd in the remaining thin silicon film. Impurity ions of the second conductive type are then implanted through the opening Pmsk in the P⁺ mask into this region 130f. For example, boron difluoride ions (BF₂) may be implanted at a dose of 1×10¹⁵ cm⁻² to 5×10¹⁵ cm⁻². The symbol P⁺ is used in FIG. 23B to indicate this comparatively high concentration of ions of a p-type impurity. Since all parts of the remaining thin silicon film except region 130f are covered by the P⁺ mask, the impurity ions are implanted only into the region 130f that will become the body terminal region.

In the above description, first impurity ions of the first conductive type are implanted into regions 130a and 130b and then impurity ions of the second conductive type are implanted into region 130f, but this order may be reversed.

Next, an annealing process is performed to diffuse the implanted ions. The impurity ions of the first conductive type (e.g., phosphorus ions) are thereby diffused into regions 130a and 130b to form a high-concentration diffusion region of the first conductivity type (e.g., an N⁺ region), and the impurity ions of the second conductive type (e.g., BF₂ ions) are diffused into region 130f to form a high-concentration diffusion region of the second conductivity type (e.g., a P⁺ region).

Next, the P⁺ mask is removed from the surface of the polysilicon film 160, leaving the structure shown in FIGS. 23A and 23B.

For a p-channel MOS varactor Vaa, boron difluoride ions may be implanted into the source and drain regions 130a, 130b, and phosphorous ions may be implanted into the body terminal region 130f.

(11) Salicide Formation

Next, salicide layers 130aa, 130ba, 130fa, 160a are formed in the surfaces of the source and drain regions 130a, 130b, the body terminal region 130f, and the polysilicon film 160 to obtain the structure shown in FIGS. 24A and 24B.

In this step, first cobalt (Co) is deposited on the exposed silicon surfaces 130s and the surface 160s of the polysilicon film 160. Then heat treatment is carried out, causing the silicon and cobalt to react thermally to form the salicide layers 130aa, 130ba, 130fa, 160a.

Next, known photolithography and etching methods are used to selectively etch the remaining silicon and polysilicon surfaces 130s, 160s to remove any cobalt that has not reacted with the silicon or polysilicon material.

The purpose of forming the salicide layers 130aa, 130ba, 130fa, 160a is to create low-resistance electrical paths across the surface of the polysilicon film 160 and the surfaces of regions 130a, 130b, 130f in the remaining thin silicon film, so that the polysilicon film 160 and regions 130a, 130b, and 130f can function effectively as the gate electrode, source electrode, drain electrode, and body terminal region tbd, respectively.

(12) Dielectric Film Formation

Next, a dielectric (SiO₂) film 172 is formed on the entire wafer surface to obtain the structure shown in FIGS. 25A and 25B. The dielectric film 172 may be formed by any suitable method, such as CVD followed by CMP. In this embodiment, the dielectric film 172 is approximately 100 nm thick and covers the field oxide regions 130d, 130e, 130g, 130h as well as the source, gate, and drain electrode surfaces and the surface of the body terminal region.

(13) Contact Hole Formation

Next, contact holes 174a to 174d are formed in the dielectric film 172 to obtain the structure shown in FIGS. 26A and 26B. In this step, known photolithography and etching methods are used to selectively etch the dielectric film 172 and thereby form contact holes 174a to 174d extending to the salicided surfaces of the source and drain regions 130a, 130b, the body terminal region 130f, and the interconnecting lead region 162a of the polysilicon film 160.

(14) Contact and Metal Terminal Formation

Next, contacts 180a to 180d are formed in the contact holes 174a to 174d, respectively, and metal terminals 190a, 190c, and 190d are formed on the contacts 180a and 180b, 180c, and 180d, respectively, thereby obtaining the structure shown in FIGS. 27A and 27B. The contacts 180a to 180d may be formed of any suitable material, such as tungsten (W), and by any suitable method, such as CVD followed by CMP. The metal terminals 190a, 190c, 190d may be formed of any suitable material, such as aluminum (Al) or an alloy thereof, and may be patterned by any suitable method, such as photolithography and etching.

This step completes the fabrication of a varactor Vaa with a body terminal.

Oscillation Frequency Range of the VCO FIG. 28 is a graph illustrating a pair of voltage-capacitance curves of a varactor Vaa with a body terminal fabricated in the integrated VCO circuit as described above. The horizontal axis represents the control voltage Vc1 in volts; the vertical axis represents the varactor capacitance in farads in exponential notation.

Absent any adjustment voltage Vcs1, the varactor Vaa with the body terminal exhibits substantially the same voltage-capacitance curve as the conventional varactor Va, indicated by the dotted line marked with black squares. The capacitance range is from about 0.21 pF to about 0.45 pF.

When an adjustment voltage Vcs1 is applied to the body terminal Tbd (metal terminal 190d in FIG. 27B), the voltage-capacitance curve of the varactor Vaa shifts to the position indicated by the solid line marked with black diamonds. The shift is a parallel translation toward the upper right in the drawing: on the control voltage scale (Vc1), the curve shifts in the positive direction by +0.3 V; on the varactor capacitance scale the curve shifts in the positive direction by +0.05 pF. The shape of the curve remains substantially unchanged. The capacitance range is from about 0.26 pF to about 0.50 pF.

Referring once again to FIG. 8, although the varactors C1a, C2a with body terminals could be adjusted and controlled independently, it is preferable for both varactors C1a, C2a to be adjusted and controlled in the same way so that they operate with the same voltage-capacitance curve. Accordingly, the gate electrodes of varactors C1a, C2a are both connected through node N3 to a single common control voltage input terminal TVc1 and receive the same control voltage Vc1. Similarly, the body terminals Tbd of varactors C2a, C2a are both connected to a single common adjustment voltage terminal TVcs1 and receive the same adjustment voltage Vcs1.

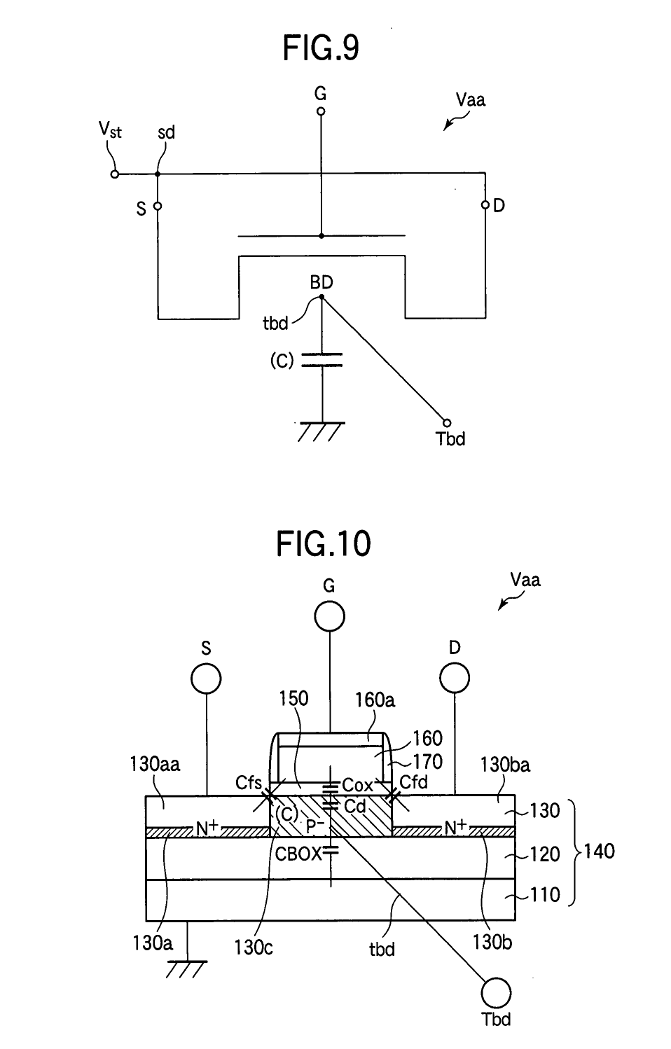

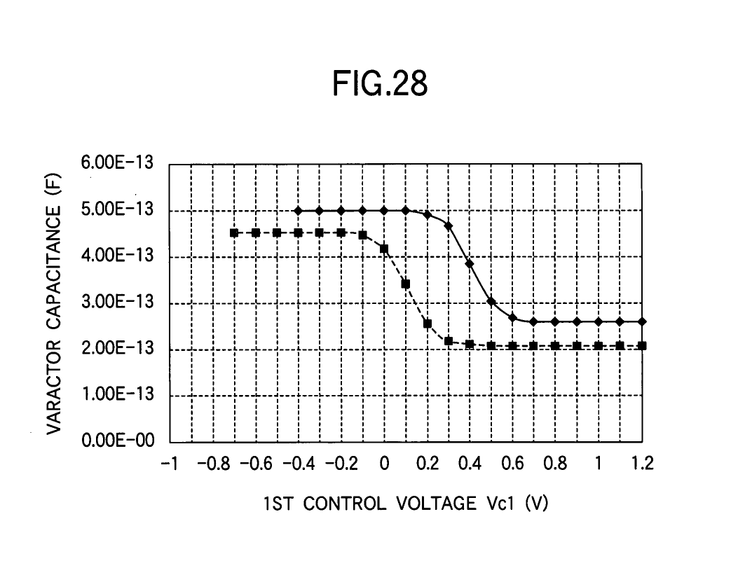

The oscillation frequency range of the novel VCO 45a will now be described with reference to the voltage-frequency graph in FIG. 29. The horizontal axis in FIG. 29 indicates the control voltage Vc1 in volts (V) and the vertical axis indicates the oscillation frequency (freq) in hertz (Hz), using exponential notation. The dotted curve is the voltage-frequency curve of VCO 45a in the absence of an adjustment voltage Vcs1; this curve is identical to the conventional curve shown in FIG. 7. The solid curve is the voltage-frequency curve of the novel 45a when an adjustment voltage Vcs1 is applied to the adjustment voltage terminal TVcs1.

The circuit parameters that produced the curves in FIG. 29 are the same as those that produced the conventional curve in FIG. 7: the DC voltage at nodes N1, N2 is 0.3 V, the sum of the inductances of inductors L1, L2 is 2.28 nH, and the sum of the parasitic capacitances of transistors M1, M2 is 1.5 pF.

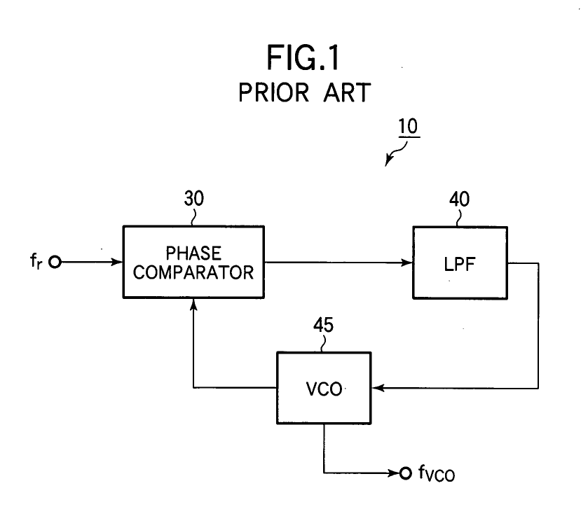

Double-headed arrows A1 to A4 are shown in FIG. 29. Arrow A1 indicates the frequency range specified by an application, arrow A2 indicates the variable range of the control voltage Vc1 (output from the LPF 40 in FIG. 1) applied to the varactors C1a, C2a of the VCO 45a, arrow A3 indicates the oscillation frequency range of the VCO 45a before curve shifting control, and arrow A4 indicates the oscillation frequency range of the VCO 45a after curve shifting control.

Arrows A1 to A3 are the same as in FIG. 7: the specified application frequency range (arrow A1) is 2.40 GHz to 2.50 GHz with a center value of 2.45 GHz, the variable range of the control voltage Vc1 is 0.1 V to 0.9 V (arrow A2), and the oscillation frequency range of the VCO 45a before the curve shifting control is 2.46 GHz to 2.55 GHz (arrow A3). Application of an adjustment voltage Vcs1 to the adjustment voltage terminal TVcs1 shifts the curve so that the oscillation frequency range (arrow A4) for the same range of control voltages (0.1 V to 0.9 V) is 2.36 GHz to 2.52 GHz.

The shift of the voltage-frequency curve illustrated in FIG. 29 is by +0.3 V in the positive direction of the control voltage Vc1 and by about −0.03 GHz in the negative direction of the oscillation frequency. Overall, accordingly, the curve is shifted down and to the right. The shift is a parallel translation, not changing the shape of the curve.

If the curve is shifted as shown in FIG. 29, the oscillation frequency range A4 covers the specified application range A1, and the center of the application frequency range (2.45 GHz) corresponds to a control voltage (about 0.45 V) close to the center (0.5 V) of the variable range of the control voltage Vc1. In this state, the phase-locked loop shown in FIG. 1 can lock at frequencies throughout the specified application range. Moreover, this desirable adjustment of the variable frequency range is accomplished electronically, simply by applying a voltage to the adjustment voltage terminal TVcs1; it does not require a redesign of the VCO circuit or a shift of the variable range of the control voltage Vc1.

### Modification of the VCO Structure

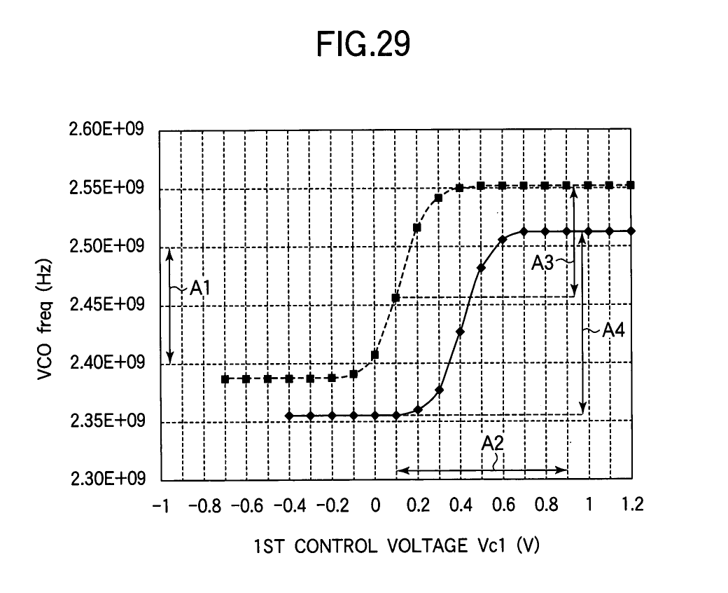

A modification of the novel VCO 45a will be described below with reference to FIG. 30. The modified VCO 46a has the same structure as the VCO 45a in FIG. 8, except that the VCO 46a has another pair of MOS varactors C3a, C4a with body terminals, which are connected in series on a wiring path I6. Varactors C3a and C4a are similar to varactors C1a and C2a, having the structure of the exemplary varactor Vaa shown in FIGS. 9 to 13. Varactor C3a has source (S) and drain (D) electrodes both connected to a node N4 and a gate (G) electrode connected to a node N6. The common interconnection of the source and drain electrodes forms one terminal of the capacitor, denoted sd3; the gate electrode forms the other terminal. Similarly, varactor C4a has a source-drain terminal sd4 connected to a node N5 and a gate electrode G connected to node N6.

The control voltage Vc1 supplied to the gate electrodes of varactors C1a, C2a will be referred to as the first control voltage, and the terminal TVc1 from which it is supplied will be referred to as the first control voltage input terminal. The control voltage Vc2 supplied to the gate electrodes of varactors C3a, C4a will be referred to as the second control voltage, and the terminal TVc2 from which it is supplied will be referred to as the second control voltage input terminal. The second control voltage input terminal TVc2 is connected to the node N6 between varactors C3a and C4a on wiring path I6.

Varactors C3a, C4a with body terminals may be separately controlled by the adjustment voltages Vcs2 supplied through their body terminals Tbd. As with varactors C1a and C2a, however, it is preferable for the voltage-capacitance curves of both varactors C3a, C4a to be controlled together so that both varactors C3a, C4a operate in the same fashion. Therefore, as shown in FIG. 30, the body terminals Tbd of both varactors C3a, C4a are connected to a second adjustment voltage terminal TVcs2, through which an adjustment voltage is supplied to the VCO 46a from an external circuit. The VCO 46a accordingly receives a first adjustment voltage VCs1 that shifts the voltage-capacitance curves of the varactors C1a and C2a, and a second voltage-capacitance voltage VCs2 that shifts the voltage-capacitance curves of varactors C3a and C4a.

The node N4 at one end of wiring path I6 is disposed on wiring path I1 between node N1 and transistor M1, and the node N5 at the other end of wiring path I6 is disposed on wiring path I2 between node N2 and transistor M2. Varactors C3a and C4a are accordingly connected in parallel with varactors C1a and C2a.

The second control voltage Vc2 and second adjustment voltage Vcs2 control varactors C3a and C4a in the same way that the first control voltage Vc1 and first adjustment voltage Vcs1 control varactors C1a and C2a, as described in the embodiment above.

When this VCO 46a operates, the constant current drawn by the current source Es on path I4 is matched by a proportional current on path I5, which is equal to the sum of the currents on paths I1 and I2. The cross-coupled transistors M1 and M2 switch on and off alternately, causing current to shift back and forth between paths I1 and I2 under the amplifying action of the transistors M1, M2, the charging and discharging of the varactors C1a to C4a, and the inductive kick of the inductors L1, L2. The voltage at nodes N1 and N4 varies sinusoidally while the voltage at nodes N2 and N5 varies in a complementary sinusoidal fashion. These node voltages are output to a buffer circuit (not shown) that amplifies them to generate the VCO output signal.

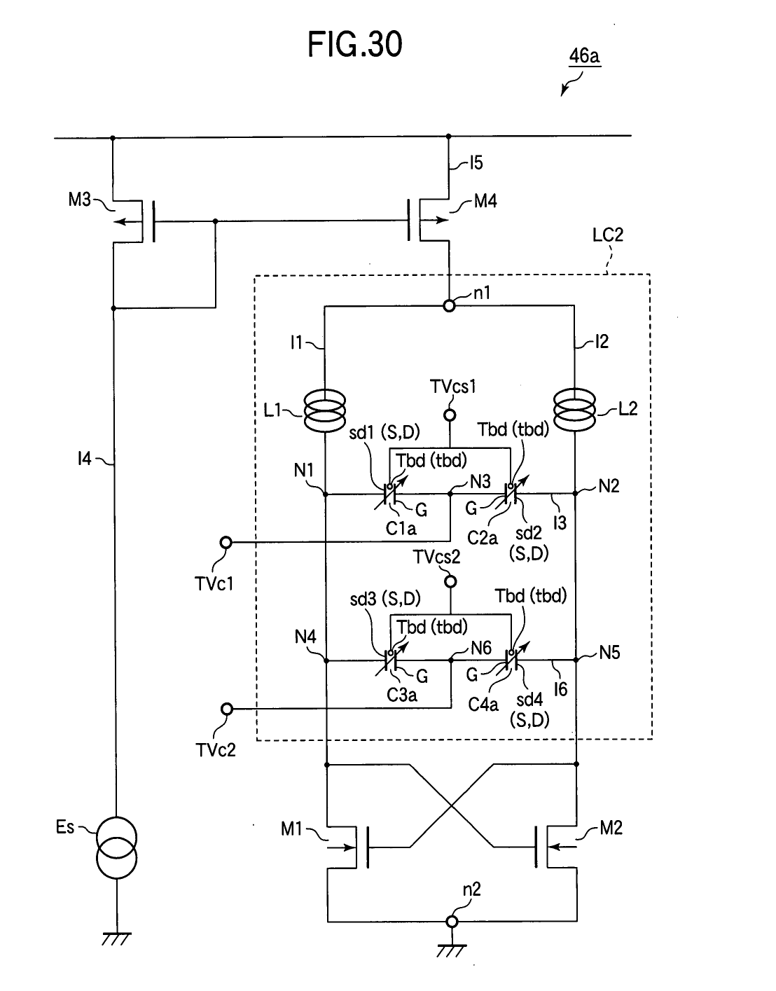

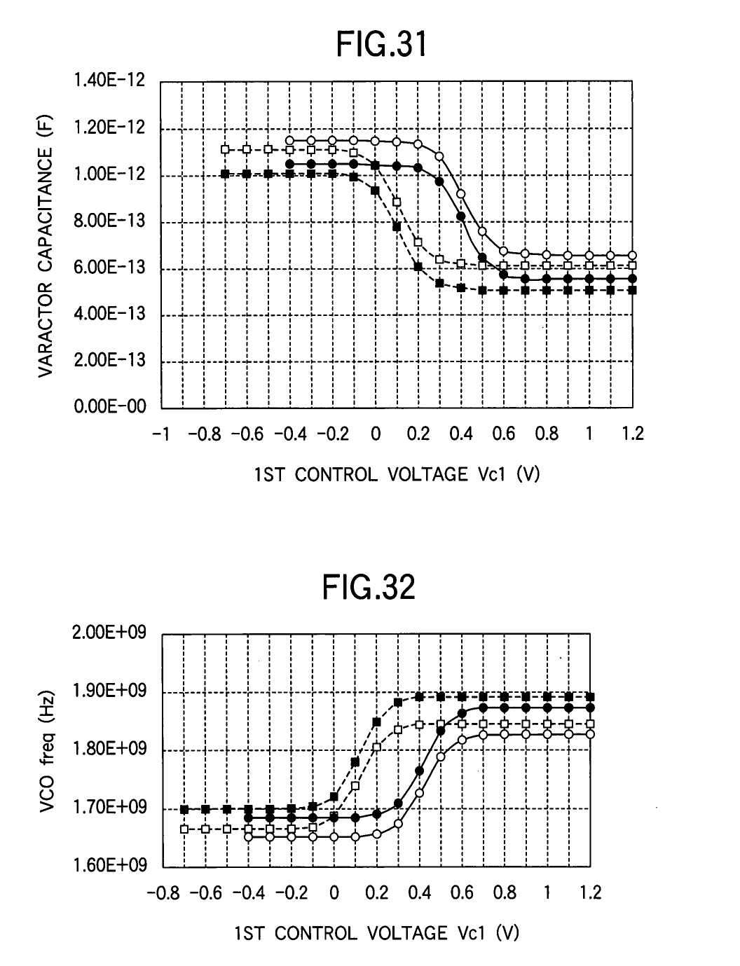

The presence of two pairs of varactors on parallel paths with independent adjustment voltages Vcs1 and Vcs2 provides VCO 46a with a greater range of selectable voltage-capacitance and voltage-frequency curves. This is illustrated in FIGS. 31 and 32. In FIG. 31, the horizontal axis represents the first control voltage Vc1 and the vertical axis represents the varactor capacitance, as in FIG. 28, except that the capacitance is the total capacitance on parallel paths I1 and I6. In FIG. 32, the horizontal axis represents the first control voltage Vc1 and the vertical axis represents oscillation frequency, as in FIG. 29. The curves marked with black circles and squares indicate shifts that can be accomplished by changing the first adjustment voltage with the second adjustment voltage at one level; the curves marked with white circles and squares indicate shifts that can be accomplished by changing the first adjustment voltage with the second adjustment voltage at another level. The capacitance values are higher than in FIG. 28 and the frequency values are lower than in FIG. 29 because there are more varactors. If the variable range of the first control voltage Vc1 is from 0.1 V to 0.9 V as before, the total available frequency range in FIG. 32 is from about 1.65 GHz to 1.89 GHz, which is considerably wider than the range available from either the pair of curves with black markings or the pair of curves with white markings.

This modification of the novel VCO structure thus provides an enhanced capability to adjust the frequency range of the VCO electronically to cover the desired application frequency range.

### PLL Circuit Configuration

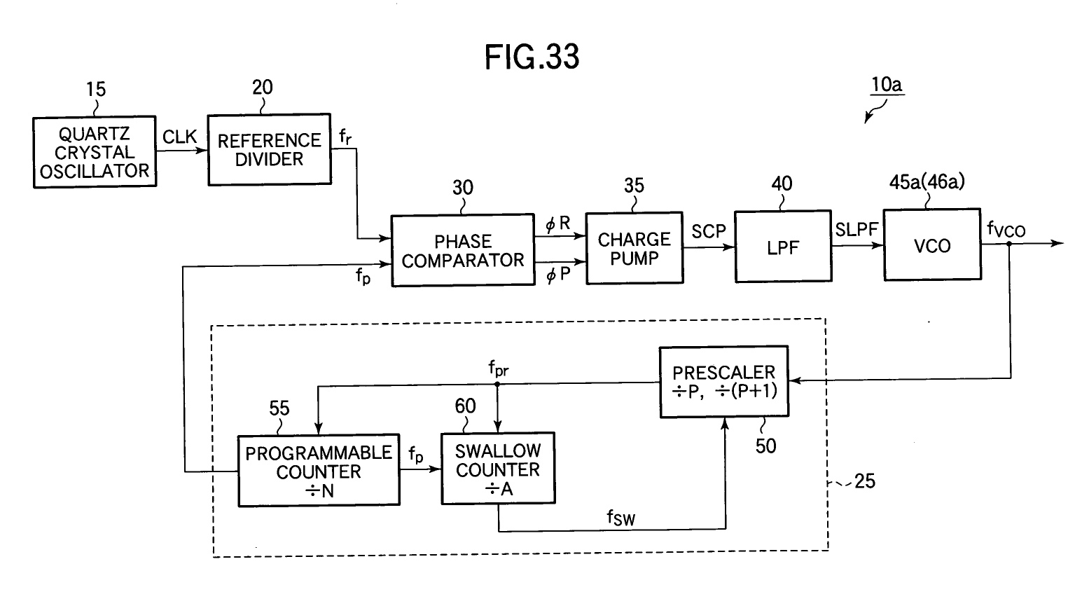

The configuration of a PLL circuit using the novel VCO will be described below with reference to FIG. 33.

The PLL 10a in FIG. 33 comprises a quartz crystal oscillator 15, a reference divider 20, a comparison divider 25, a phase comparator 30, a charge pump 35, an LPF 40, and the novel VCO 45a (or VCO 46a). This PLL 10a differs from the PLL 10 shown in FIG. 1 by its use of the novel VCO, and by inserting the charge pump 35 between the phase comparator 30 and LPF 40 and inserting the comparison divider 25 between the VCO 45a (or 46a) and phase comparator 30. A further difference is that in the PLL 10a, the phase comparator 30 outputs two comparator output signals pulse signals φR, φP to the charge pump 35. The LPF 40 outputs a single filtered signal SLPF to the VCO 45a as a control voltage signal, and the VCO 45a returns the VCO output signal f_{VCO} to the comparison divider 25.

The quartz crystal oscillator 15, reference divider 20, and phase comparator 30 are coupled in cascade, and the comparison divider 25, phase comparator 30, charge pump 35, LPF 40, and VCO 45a are connected in loop.

The quartz crystal oscillator 15 includes a quartz crystal (not shown) that vibrates at a specific frequency. The quartz crystal oscillator 15 generates a reference clock signal CLK from the crystal vibrations and outputs the reference clock signal CLK to the reference divider 20.

The reference divider 20 receives the reference clock signal CLK from the quartz crystal oscillator 15, divides the frequency of the reference clock signal CLK by an externally preset ratio to generate a reference signal fᵣ, and supplies the reference signal fᵣ to the phase comparator 30.

The comparison divider 25 receives the VCO output signal f_{VCO} from the VCO 45a, divides its frequency by an externally preset ratio to generate a divided signal fₚ, and supplies the divided signal fₚ to the phase comparator 30.

In FIG. 33, the comparison divider 25 comprises a dual modulus prescaler 50 (referred to below simply as a prescaler), a programmable counter 55, and a swallow counter 60.

The prescaler 50 receives the VCO output signal f_{VCO} from the VCO 45a and divides its frequency by a selectable ratio to generate a prescaled signal fₚᵣ. In this example, the prescaler 50 selects one of two externally preset ratios p and p+1, where p is an integer. The prescaler 50 outputs the prescaled signal fₚᵣ to the programmable counter 55 and swallow counter 60.

The prescaler 50 has two operating modes corresponding to the two dividing ratios: a relatively slow mode in which it divides the VCO output signal f_{VCO} by the ratio p+1, and a relatively fast mode in which it divides the VCO output signal f_{VCO} by the ratio p. The prescaler 50 operates initially in the slow mode, and switches to the fast mode upon receiving a signal f_{sw} output from the swallow counter 60. When the swallow counter 60 deactivates the f_{sw} signal, the operating mode of the prescaler 50 switches from the fast mode back to the slow mode.

The programmable counter 55 receives the prescaled signal fₚᵣ from the prescaler 50 and divides its frequency by a programmable integer ratio N to generate the divided signal fₚ. The programmable counter 55 outputs the divided signal fₚ to the phase comparator 30.

The programmable counter 55 operates by counting rising edges of the divided signal fₚ. The count proceeds from zero to N-1, then returns to zero on the next rising edge and starts again. Each time the count value returns to zero, the programmable counter 55 outputs one pulse of the divided signal fₚ. The divided signal fₚ is also output to the swallow counter 60 as a trigger signal.

The swallow counter 60 has the function of changing the operating mode of the prescaler 50.

The swallow counter 60 receives the divided signal fₚ from the programmable counter 55 and the prescaled signal fₚᵣ from the prescaler 50, and uses the divided signal fₚ as a trigger to start counting pulses of the prescaled signal fₚᵣ. In this way the swallow counter 60 divides each period of the divided signal fₚ into two parts.

The swallow counter 60 counts pulses of the prescaled signal fₚᵣ from zero up to an externally preset integer A. When the count value reaches A, the swallow counter 60 activates the signal f_{sw} by driving it to the high logic level, causing the prescaler 50 to switch from the slow mode to the fast mode. The swallow counter 60 then stops counting until it receives the next pulse of the divided signal fₚ from the programmable counter 55, at which point the swallow counter 60 deactivates the f_{sw} signal and starts counting pulses of the prescaled signal fₚᵣ again from zero.

While the swallow counter 60 is not counting, it continues to hold the f_{sw} signal at the high logic level, thereby holding the prescaler 50 in the fast mode. While the swallow counter 60 is counting, it holds the f_{sw} signal at the low logic level, thereby holding the prescaler 50 in the slow mode.

The parameters A and N are set externally according to the desired VCO output frequency. The prescaling parameter p may also be set externally if the prescaler 50 is programmable.

The function of the phase comparator 30 is to compare the reference signal fᵣ output from the reference divider 20 with the divided signal fₚ output from the comparison divider 25.

The phase comparator 30 receives the reference signal fᵣ from the reference divider 20 and the divided signal fₚ from the comparison divider 25, compares them, and generates the signals φR, φP according to the frequency and phase differences between the reference signal fᵣ and the divided signal fₚ. As long as the reference signal fᵣ and the divided signal fₚ agree in frequency and phase, both output signals φR, φP remain inactive. When the reference signal fᵣ leads the divided signal fₚ, output signal φR becomes active. When the divided signal fₚ leads the reference signal fᵣ, output signal φP becomes active. The phase comparator 30 outputs both signals φR, φP to the charge pump 35.

The signal SCP output from the charge pump 35 has a direct-current (DC) component that rises and falls according to the received pulse signals φR, φP, rising while φR is active and falling while φP is active. The charge pump 35 outputs the SCP signal to the LPF 40.

The LPF 40 smoothes the SCP signal by removing high-frequency components, leaving the DC component, which is output to the VCO 45a (or 46a) as the filtered signal SLPF.

The VCO 45a uses the filtered signal SLPF as its control voltage Vc1. If the modified VCO 46a is employed, the filtered signal is used as both the first and second control voltages Vc1 and Vc2. The VCO output signal f_{VCO} accordingly has a frequency that depends on the voltage value of the filtered signal SLPF.

The VCO output signal f_{VCO} is output to an external circuit (not shown) for use in an application, and is also returned to the comparison divider 25 for feedback loop control as described above. Although the VCO output signal f_{VCO} itself may be fed back to the comparison divider 25 as shown in FIG. 33, complementary signals from nodes N1 and N2 (nodes N1, N2, N4, and N5 for VCO 46a) may be fed back as noted previously, and the prescaler 50 may operate differentially.

When the frequency and phase differences between the reference signal fᵣ and the divided signal fₚ are zero, the PLL 10a enters the locked state and holds the VCO output signal f_{VCO} at a frequency that is a fixed multiple of the frequency of the reference signal fᵣ. The frequency ratio of the VCO output signal f_{VCO} to the reference signal fᵣ is determined by the parameters A, N, and p. Since the frequency of the reference signal is fixed, the VCO 45a (or 46a) operates at a frequency that is externally set by A and N (or A, N, and p). Depending on the values of A, N, and p, the VCO output frequency may be an integer or non-integer multiple of the reference frequency.

When the frequency or phase difference between the reference signal fᵣ and the divided signal fₚ is not zero, the PLL 10a is in the unlocked state. In this state the PLL 10a operates so as to raise or lower the frequency of the VCO output signal f_{VCO} and thereby gradually reduce the difference between the reference signal fᵣ and the divided signal fₚ until the locked state is reached.

When the PLL 10a is in the locked state, the values of parameters A and N (or A, N, and p) may be changed by external control, thereby altering the frequency of the divided signal fₚ. The PLL 10a then enters the unlocked state as the divided signal fₚ begins to lead or lag the reference signal fᵣ.

The PLL 10a now repeats the following operation: the VCO 45a (or 46a) receives the filtered signal SLPF from the LPF 40 as a feedback signal corresponding to the VCO output signal f_{VCO} that it has been supplying to the comparison divider 25; the VCO 45a (or 46a) adjusts the frequency of the VCO output signal f_{VCO} according to the voltage level of the filtered signal SLPF in such a way as to reduce the phase and frequency difference between the reference signal fᵣ and the divided signal fₚ, and begins f_{VCO} output at the adjusted frequency; the phase comparator 30, charge pump 35, and LPF 40 respond to the reduced difference by altering the value of the filtered signal SLPF; the VCO 45a (or 46a) responds to the altered SLPF value by further altering the frequency of the VCO output signal f_{VCO}. Eventually this process reduces the frequency and phase differences between the reference signal fᵣ and the divided signal fₚ to zero and the PLL 10a reenters the locked state. The PLL 10a now holds the VCO output signal f_{VCO} at a new frequency that is a different multiple of the frequency of the reference signal fᵣ.

The PLL 10a in FIG. 33 can be programmed for a wide range of VCO output frequencies, corresponding to different values of the parameters A and N, or (A, N, and p). The invented VCO 45a (or 46a) is suitable for use in this type of phase-locked loop because its curve shifting control feature enables it to cover a wide frequency range.

This invention is not limited to the above embodiment and modification. For example, as already noted, p-channel varactors may be used instead of n-channel varactors. The following are a few further possible variations.

The body region BD need not be doped with an impurity of opposite conductive type to the conductive type of the source and drain diffusion regions. The same impurity as implanted into the source and drain diffusion regions may also be implanted into the body region, but at a lower concentration. The main body region may also be an intrinsic silicon region into which no impurity ions of either conductive type are implanted.

The roles of the two main terminals of the varactors may be reversed. In FIG. 8, for example, the gate electrodes G of varactors C1a and C2a may be connected to nodes N1 and N2, and the source and drain electrodes of varactors C1a and C2a may be connected to node N3. In this case, the common source-drain terminals (sd1, sd2) are used as control terminals, receiving the control voltage Vc1. The capacitance then varies in the reverse manner, increasing as the voltage applied to the source and drain electrodes increases in the positive direction.

The MOS varactors may be formed on a silicon-on-sapphire (SOS) wafer instead of an SOI wafer with a buried oxide film.

Those skilled in the art will recognize that still further variations are possible within the scope of the invention, which is defined in the appended claims.

What is claimed is:

1. A voltage controlled oscillator comprising:
a first reference node receiving a first current;
a second reference node receiving a first fixed potential;
a first inductor;
a second inductor;
a first metal-oxide-semiconductor (MOS) transistor;
a second MOS transistor cross-coupled with the first MOS transistor;
a first internal node coupled through the first inductor to the first reference node and through the first MOS transistor to the second reference node;
a second internal node coupled through the second inductor to the first reference node and through the second MOS transistor to the second reference node;
a third internal node receiving a first control voltage signal;
a first MOS varactor having a pair of impurity diffusion regions and an electrode, the pair of impurity diffusion regions being electrically connected to one of the first internal node and the third internal node, the electrode being electrically connected to another one of the first internal node and the third internal node;
a second MOS varactor having a pair of impurity diffusion regions and an electrode, the pair of impurity diffusion regions being electrically connected to one of the second internal node and the third internal node, the electrode being electrically connected to another one of the second internal node and the third internal node; and
a first input terminal receiving a first adjustment voltage signal for adjusting a relationship between the first control voltage signal and respective capacitances of the first and second MOS varactors; wherein
each of the first and second MOS varactors includes a silicon layer in which the pair of impurity diffusion regions are formed, an insulating film separating the electrode from the silicon layer, and a body region disposed in the silicon layer, the body region including a main body region and a body terminal region, the main body region being disposed below the electrode and between the impurity diffusion regions, the body terminal region being electrically connected to the first input terminal.

2. The voltage controlled oscillator of claim 1, wherein the voltage controlled oscillator is formed in a silicon-on-insulator substrate including said silicon layer and an insulating layer underlying the silicon layer.

3. The voltage controlled oscillator of claim 2, wherein the insulating layer is a buried oxide layer.

4. The voltage controlled oscillator of claim 1, wherein the impurity diffusion regions are doped with an impurity of a first conductivity type;

5. The voltage controlled oscillator of claim 4, wherein the main body region is doped with an impurity of a second conductivity type opposite to the first conductivity type.

6. The voltage controlled oscillator of claim 5, wherein the body terminal region is doped with an impurity of a second conductivity type at a higher concentration than the main body region.

7. The voltage controlled oscillator of claim 4, wherein the main body region is doped with an impurity of the first conductivity type.

8. The voltage controlled oscillator of claim 7, wherein the main body region is doped at a lower concentration than the impurity diffusion regions.

9. The voltage controlled oscillator of claim 7, wherein the body terminal region is doped with an impurity of the first conductivity type at a higher concentration than the main body region.

10. The voltage controlled oscillator of claim 4, wherein the main body region is an intrinsic silicon region.

11. The voltage controlled oscillator of claim 1, each of the MOS varactors further including a first field oxide region and a second field oxide region disposed on opposite sides of the silicon layer, the body region having a first end and a second end, the first end meeting the first field oxide region, the second end meeting the second field oxide region, the electrode being partly disposed on the first field oxide region and extending partway toward the second field oxide region, the body terminal region being disposed at the second end of the body region.

12. The voltage controlled oscillator of claim 1, further comprising:
a third reference node receiving a second fixed potential;
a current source drawing a second current;
a third MOS transistor conducting the second current between the third reference node and the current source; and
a fourth MOS transistor connected in a current mirror configuration with the third MOS transistor to conduct the first current between the third reference node and the first reference node.

13. The voltage controlled oscillator of claim 1, further comprising:
a fourth internal node coupled to the first internal node and through the first inductor to the first reference node, and coupled through the first MOS transistor to the second reference node;
a fifth internal node coupled to the second internal node and through the second inductor to the first reference node, and coupled through the second MOS transistor to the second reference node;
a sixth internal node receiving a second control voltage signal;
a third MOS varactor having a pair of impurity diffusion regions and an electrode, the pair of impurity diffusion regions being electrically connected to one of the fourth internal node and the sixth internal node, the electrode being electrically connected to another one of the fourth internal node and the sixth internal node; and
a fourth MOS varactor having a pair of impurity diffusion regions and an electrode, the pair of impurity diffusion regions being electrically connected to one of the fifth internal node and the sixth internal node, the electrode being electrically connected to another one of the fifth internal node and the sixth internal node;
a second input terminal receiving a second adjustment voltage signal for adjusting a relationship between the second control voltage signal and respective capacitances of the third and fourth MOS varactors; wherein
each of the third and fourth MOS varactors includes a silicon layer in which the pair of impurity diffusion regions are formed, an insulating film separating the electrode from the silicon layer, and a body region disposed in the silicon layer, the body region including a main body region and a body terminal region, the main body region being disposed below the electrode and between the impurity diffusion regions, the body terminal region being electrically connected to the second input terminal.

14. The voltage controlled oscillator of claim 13, wherein the third and fourth MOS varactors are structurally identical to the first and second MOS varactors.

15. The voltage controlled oscillator of claim 13, further comprising a second adjustment voltage terminal receiving a second adjustment voltage signal, the second adjustment voltage terminal being electrically connected to the body terminal region in the third MOS varactor and the body terminal region in the fourth MOS varactor.

16. The voltage controlled oscillator of claim 13, further comprising:
a third reference node receiving a second fixed potential;
a current source drawing a second current;
a third MOS transistor conducting the second current between the third reference node and the current source; and
a fourth MOS transistor connected in a current mirror configuration with the third MOS transistor to conduct the first current between the third reference node and the first reference node.

17. The voltage controlled oscillator of claim 1, wherein the first control voltage signal has a voltage level that varies during operation of the voltage controlled oscillator and the adjustment voltage has a fixed voltage level during operation of the voltage controlled oscillator.
